(19) United States
(12) Patent Application Publication
(10) Pub. No.: US 2019/0243244 A1
(43) Pub. Date: Aug. 8, 2019

(54) RADIATION-SENSITIVE RESIN COMPOSITION AND RESIST PATTERN-FORMING METHOD

(71) Applicant: JSR CORPORATION, Tokyo (JP)

(72) Inventors: Tetsurou KANEKO, Tokyo (JP); Takehiko Naruoka, Tokyo (JP)

(73) Assignee: JSR CORPORATION, Tokyo (JP)

(21) Appl. No.: 16/382,353

(22) Filed: Apr. 12, 2019

Related U.S. Application Data
(63) Continuation of application No. PCT/JP2017/036196, filed on Oct. 4, 2017.

(30) Foreign Application Priority Data
Oct. 13, 2016 (JP) 2016-201995

(51) Int. Cl. G03F 7/039; G03F 7/004; G03F 7/16; G03F 7/20; G03F 7/38; G03F 7/32; C08F 212/14

(52) U.S. Cl. CPC G03F 7/039; G03F 7/0045; G03F 7/162; G03F 7/168; C08F 212/14; G03F 7/2037; G03F 7/38; G03F 7/322; G03F 7/2004

(57) ABSTRACT

A radiation-sensitive resin composition includes a polymer component having first, second and third structural units, and a radiation-sensitive acid generating component including first and second radiation-sensitive acid generating agents. The first structural unit includes a group represented by formula (1). The second structural unit includes a hydroxyl group bonded to an aromatic ring. The third structural unit includes an acid-labile group. A sulfonic acid generated by the first acid generating agent includes a carbon atom that is adjacent to a sulfo group, and a fluorine atom or monovalent fluorinated hydrocarbon group bonded to the carbon atom. A sulfonic acid generated by the second acid generating agent includes a carbon atom that is adjacent to a sulfo group, and a carbon atom that is adjacent to the carbon atom, wherein neither a fluorine atom nor a monovalent fluorinated hydrocarbon group is bonded to the carbon atoms.

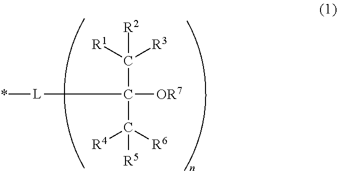

### CROSS-REFERENCE TO RELATED APPLICATIONS

The present application is a continuation application of International Application No. PCT/JP2017/036196, filed Oct. 4, 2017, which claims priority to Japanese Patent Application No. 2016-201995, filed Oct. 13, 2016. The contents of these applications are incorporated herein by reference in their entirety.

### BACKGROUND OF THE INVENTION

### Field of Invention

The present invention relates to a radiation-sensitive resin composition and a resist pattern-forming method.

### Discussion of the Background

Miniaturization of various types of electronic device structures such as semiconductor devices and liquid crystal devices has been accompanied by demands for further microfabrication of resist patterns in lithography processes, and thus a variety of radiation-sensitive resin compositions have been studied. Such radiation-sensitive resin compositions generate in light-exposed regions an acid upon irradiation with exposure light such as e.g., a far ultraviolet ray such as an ArF excimer laser, an extreme ultraviolet ray (EUV) or an electron beam to produce a difference in a rate of dissolution in a developer solution between the light-exposed regions and light-unexposed regions through a catalytic action of the acid, thereby allowing a resist pattern to be formed on a substrate.

Such a radiation-sensitive resin composition is required to enable a resist pattern to be formed with a high process yield, the resist pattern being highly accurate and being superior not only in resolution and rectangular configuration of a cross-sectional shape of the resist pattern, but also in an LWR (Line Width Roughness) performance in line-and-space pattern formation, and CDU (Critical Dimension Uniformity) in hole pattern formation, as well as in exposure latitude. To address the demands, the structure of the polymer contained in the radiation-sensitive resin composition has been extensively studied, and it is known that incorporation of a lactone structure such as a butyrolactone structure and a norbornanelactone structure can enhance the adhesiveness of the resist pattern to a substrate, and improve the aforementioned performances (see Japanese Unexamined Patent Application, Publication Nos. H11-212265, 2003-5375 and 2008-83370).

### SUMMARY OF THE INVENTION

According to an aspect of the present invention, a radiation-sensitive resin composition includes: a polymer component including in a single polymer or different polymers, a first structural unit, a second structural unit and a third structural unit; and a radiation-sensitive acid generating component including a first radiation-sensitive acid generating agent and a second radiation-sensitive acid generating agent. The first structural unit includes a group represented by formula (1). The second structural unit includes a hydroxyl group bonded to an aromatic ring. The third structural unit includes an acid-labile group. An acid to be generated from the first radiation-sensitive acid generating agent is a first sulfonic acid, and an acid to be generated from the second radiation-sensitive acid generating agent is a second sulfonic acid or a carboxylic acid. The first sulfonic acid includes: a first carbon atom that is adjacent to a first sulfo group; and a fluorine atom bonded to the first carbon atom, or a monovalent fluorinated hydrocarbon group bonded to the first carbon atom. The second sulfonic acid includes: a second carbon atom that is adjacent to a second sulfo group; and a third carbon atom that is adjacent to the second carbon atom, wherein neither a fluorine atom nor a monovalent fluorinated hydrocarbon group is bonded to the second carbon atom or the third carbon atom. The carboxylic acid includes: a fourth carbon atom that is adjacent to a carboxy group; and a fluorine atom bonded to the fourth carbon atom, or a monovalent fluorinated hydrocarbon group bonded to the fourth carbon atom.

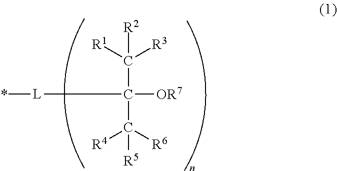

L represents an organic group having a valency of (n+1) and having 3 to 20 carbon atoms including an alicyclic structure having 3 to 20 ring atoms; R¹ to R⁶ each independently represent a hydrogen atom, a halogen atom or a monovalent organic group having 1 to 20 carbon atoms, wherein at least one of R¹ to R⁶ represents a fluorine atom or an organic group including at least one fluorine atom; R⁷ represents a hydrogen atom or a monovalent organic group having 1 to 20 carbon atoms; n is an integer of 1 to 3, wherein in a case where n is no less than 2, a plurality of R¹s are identical or different, a plurality of R²s are identical or different, a plurality of R³s are identical or different, a plurality of R⁴s are identical or different, a plurality of R⁵s are identical or different, a plurality of R⁶s are identical or different, and a plurality of R⁷s are identical or different; and * denotes a bonding site to a moiety other than the group represented by the formula (1) in the first structural unit.

According to another aspect to the present invention, a resist pattern-forming method includes applying the radiation-sensitive resin composition directly or indirectly on one face of a substrate to obtain a resist film. The resist film is exposed. The resist film exposed is developed.

### DESCRIPTION OF EMBODIMENTS

According to one embodiment of the invention, a radiation-sensitive resin composition contains:

a polymer component (hereinafter, may be also referred to as “(A) polymer component” or “polymer component (A)”) having in a single polymer or different polymers, a first structural unit (hereinafter, may be also referred to as “structural unit (I)”), a second structural unit (hereinafter, may be also referred to as “structural unit (II)”) and a third structural unit (hereinafter, may be also referred to as “structural unit (III)”); and

a radiation-sensitive acid generating component (hereinafter, may be also referred to as “(B) acid generating component” or “acid generating component (B)”) including a first radiation-sensitive acid generating agent (hereinafter, may be also referred to as “(B1) acid generating agent” or “acid generating agent (B1)”) and a second radiation-sensitive acid generating agent (hereinafter, may be also referred to as “(B2) acid generating agent” or “acid generating agent (B2)”), wherein

the structural unit (I) includes a group represented by the following formula (1) group represented by (hereinafter, may be also referred to as “group (I)”)

the structural unit (II) includes a hydroxyl group bonded to an aromatic ring, and

the structural unit (III) includes an acid-labile group, and wherein

an acid to be generated from the acid generating agent (B1) is a first sulfonic acid, and an acid to be generated from the radiation-sensitive acid generating agent (B2) is a second sulfonic acid or a carboxylic acid, wherein

the first sulfonic acid has: a first carbon atom that is adjacent to a first sulfo group; and a fluorine atom bonded to the first carbon atom, or a monovalent fluorinated hydrocarbon group bonded to the first carbon atom,

the second sulfonic acid has: a second carbon atom that is adjacent to a second sulfo group; and a third carbon atom that is adjacent to the second carbon atom, wherein neither a fluorine atom nor a monovalent fluorinated hydrocarbon group is bonded to the second and third carbon atoms, and

the carboxylic acid has: a fourth carbon atom that is adjacent to a carboxy group; and a fluorine atom bonded to the fourth carbon atom, or a monovalent fluorinated hydrocarbon group bonded to the fourth carbon atom.

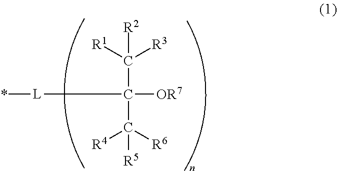

In the formula (1),

L represents an organic group having a valency of (n+1) and having 3 to 20 carbon atoms comprising an alicyclic structure having 3 to 20 ring atoms;

R¹ to R⁶ each independently represent a hydrogen atom, a halogen atom or a monovalent organic group having 1 to 20 carbon atoms, wherein at least one of R¹ to R⁶ represents a fluorine atom or an organic group comprising at least one fluorine atom;

R⁷ represents a hydrogen atom or a monovalent organic group having 1 to 20 carbon atoms;

n is an integer of 1 to 3, wherein in a case where n is no less than 2, a plurality of R¹s may be identical or different, a plurality of R²s may be identical or different, a plurality of R³s may be identical or different, a plurality of R⁴s may be identical or different, a plurality of R⁵s may be identical or different, a plurality of R⁶s may be identical or different, and a plurality of R⁷s may be identical or different; and

* denotes a bonding site to a moiety other than the group represented by the formula (1) in the first structural unit.

According to another embodiment of the invention, a resist pattern-forming method includes:

applying the radiation-sensitive resin composition according to the one embodiment directly or indirectly on one face of a substrate;

exposing a resist film obtained by the applying of the radiation-sensitive resin composition; and

developing the resist film exposed.

The radiation-sensitive resin composition and the resist pattern-forming method of the embodiments of the present invention enable formation of a resist pattern being accompanied by less LWR, less CDU and high resolution and being superior in rectangular configuration of the cross-sectional shape while attaining superior exposure latitude. Therefore, these can be suitably used in manufacture of semiconductor devices in which further progress of miniaturization is expected in the future. Hereinafter, the embodiments will be explained in detail.

### Radiation-Sensitive Resin Composition

The radiation-sensitive resin composition contains the polymer component (A) and the acid generating component (B). The radiation-sensitive resin composition may contain as favorable components, (C) an acid diffusion control agent, the solvent (D), and a polymer (hereinafter, may be also referred to as “(E) polymer” or “polymer (E)”), wherein a percentage content by mass of fluorine atoms in the polymer is greater than a percentage content by mass of fluorine atoms in the polymer component (A), and may also contain other optional component(s) within a range not leading to impairment of the effects of the present invention.

Due to containing the polymer component (A) and the acid generating component (B), the radiation-sensitive resin composition is capable of providing the LWR performance, the CDU performance, the resolution, the rectangular configuration of the cross-sectional shape and the exposure latitude (hereinafter, these taken together may be also referred to as “LWR performance, etc.”) each being superior. Although not necessarily clarified and without wishing to be bound by any theory, the reason for achieving the effects described above due to the radiation-sensitive composition having the aforementioned constitution is inferred as in the following, for example. Specifically, in the radiation-sensitive resin composition, the polymer component (A) has in addition to the acid-labile group: the group (I) that includes a fluorine atom and also includes an alicyclic structure, thus being comparatively bulky; and the aromatic ring to which a hydroxyl group bonds; therefore, a diffusion length of the acid generated may be further properly reduced. In addition, since the acid generating component (B) contains both the acid generating agent (B1) and the acid generating agent (B2), generation of a relatively strong acid and a relatively weak acid is enabled. It is considered that a synergistic effect of these leads to improvements of LWR performance, etc. Hereinafter, each component will be described.

### (A) Polymer Component

The polymer component (A) has the structural unit (I), the structural unit (II) and the structural unit (III) in a single polymer or different polymers.

The mode of the polymer component (A) is exemplified by:

(i) a single polymer having the structural unit (I), the structural unit (II) and the structural unit (III) is included;

(ii) a polymer having the structural unit (I) and the structural unit (II), and a polymer having the structural unit (III) are included;

(iii) a polymer having the structural unit (I), and a polymer having the structural unit (II) and the structural unit (III) are included;

(iv) a polymer having the structural unit (I) and the structural unit (III), and a polymer having the structural unit (II) are included;

(v) a polymer having the structural unit (I), a polymer having the structural unit (II), and a polymer having the structural unit (III) are included;

(vi) a polymer having the structural unit (I) and the structural unit (III), and a polymer having the structural unit (II) and the structural unit (III) are included; and the like. The polymer component (A) may include one, or two or more types of each of the polymers described above. Of these, the modes (i), (ii) and (vi) are preferred.

The polymer component (A) may also have in a single polymer or different polymers having the structural units (I) to (III), a structural unit (IV) that includes a lactone structure, a cyclic carbonate structure, a sultone structure or a combination thereof, and a structural unit (V) that includes an alcoholic hydroxyl group, as well as other structural unit(s) except for the structural units (I) to (V). The polymer component (A) may have one, or two or more types of each of the structural units. Hereinafter, each structural unit will be described.

Structural Unit (I)

The structural unit (I) includes a group represented by the following formula (1).

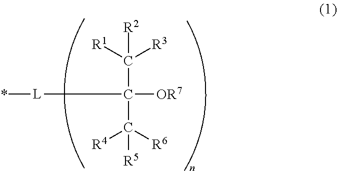

In the above formula (1), L represents an organic group having a valency of (n+1) and having 3 to 20 carbon atoms comprising an alicyclic structure having 3 to 20 ring atoms; R¹ to R⁶ each independently represent a hydrogen atom, a halogen atom or a monovalent organic group having 1 to 20 carbon atoms, wherein at least one of R¹ to R⁶ represents a fluorine atom or an organic group comprising at least one fluorine atom; R⁷ represents a hydrogen atom or a monovalent organic group having 1 to 20 carbon atoms; n is an integer of 1 to 3, wherein in a case where n is no less than 2, a plurality of R¹s may be identical or different, a plurality of R²s may be identical or different, a plurality of R³s may be identical or different, a plurality of R⁴s may be identical or different, a plurality of R⁵s may be identical or different, a plurality of R⁶s may be identical or different, and a plurality of R⁷s may be identical or different; and * denotes a bonding site to a moiety other than the group represented by the formula (1) in the first structural unit.

Examples of the alicyclic structure having 3 to 20 ring atoms included in the organic group represented by L, having a valency of (n+1) and having 3 to 20 carbon atoms include:

monocyclic saturated alicyclic structures such as a cyclopropane structure, a cyclobutane structure, a cyclopentane structure, a cyclohexane structure, a cycloheptane structure and a cyclooctane structure;

polycyclic saturated alicyclic structures such as a norbornane structure, an adamantane structure, a tricyclodecane structure and a tetracyclododecane structure;

monocyclic unsaturated alicyclic structures such as a cyclopropene structure, a cyclobutene structure, a cyclopentene structure, a cyclohexene structure, a cycloheptene structure and a cyclooctene structure;

polycyclic unsaturated alicyclic structures such as a norbornene structure, a tricyclodecene structure and a tetracyclododecene structure; and the like. Of these, the monocyclic saturated alicyclic structure and the polycyclic saturated alicyclic structure are preferred.

The monovalent organic group having 1 to 20 carbon atoms which may be represented by R¹ to R⁶ is exemplified by: a monovalent hydrocarbon group having 1 to 20 carbon atoms; a group (α) that includes a divalent hetero atom-containing group between two adjacent carbon atoms of the hydrocarbon group having 1 to 20 carbon atoms; a group obtained from the hydrocarbon group having 1 to 20 carbon atoms or the group (α) by substituting a part or all of hydrogen atoms included therein with a monovalent hetero atom-containing group; and the like.

Exemplary monovalent hydrocarbon group having 1 to 20 carbon atoms includes a monovalent chain hydrocarbon group having 1 to 20 carbon atoms, a monovalent alicyclic hydrocarbon group having 3 to 20 carbon atoms, a monovalent aromatic hydrocarbon group having 6 to 20 carbon atoms, and the like.

Examples of the monovalent chain hydrocarbon group having 1 to 20 carbon atoms include:

alkyl groups such as a methyl group, an ethyl group, a propyl group and a butyl group;

alkenyl groups such as an ethenyl group, a propenyl group and a butenyl group;

alkynyl groups such as an ethynyl group, a propynyl group and a butynyl group; and the like.

Examples of the monovalent alicyclic hydrocarbon group having 3 to 20 carbon atoms include:

monocyclic alicyclic saturated hydrocarbon groups such as a cyclopentyl group and a cyclohexyl group;

monocyclic alicyclic unsaturated hydrocarbon groups such as a cyclopentenyl group and a cyclohexenyl group;

polycyclic alicyclic saturated hydrocarbon groups such as a norbornyl group, an adamantyl group and a tricyclodecyl group;

polycyclic alicyclic unsaturated hydrocarbon groups such as a norbornenyl group and a tricyclodecenyl; and the like.

Examples of the monovalent aromatic hydrocarbon group having 6 to 20 carbon atoms include:

aryl groups such as a phenyl group, a tolyl group, a xylyl group, a naphthyl group and an anthryl group;

aralkyl groups such as a benzyl group, a phenethyl group and a naphthylmethyl group; and the like.

The hetero atom that may constitute the monovalent and divalent hetero atom-containing group is exemplified by an oxygen atom, a nitrogen atom, a sulfur atom, a phosphorus atom, a silicon atom, a halogen atom and the like. Examples of the halogen atom include a fluorine atom, a chlorine atom, a bromine atom, an iodine atom and the like.

Examples of the divalent hetero atom-containing group include —0—, —CO—, —S—, —CS—, —NR′—, groups obtained by combining at least two of the same, and the like, wherein R′ represents a hydrogen atom or a monovalent hydrocarbon group. Of these, the divalent hetero atom-containing group is preferably —O—.

Examples of the monovalent hetero atom-containing group include halogen atoms such as a fluorine atom, a chlorine atom, a bromine atom and an iodine atom, a hydroxy group, a carboxy group, a cyano group, an amino group, a sulfanyl group and the like. Of these, halogen atoms are preferred, and a fluorine atom is more preferred.

As R¹ to R⁶, a fluorine atom and the fluorinated alkyl group are preferred, a fluorine atom and a perfluoroalkyl group are more preferred, and a fluorine atom is still more preferred.

Examples of the monovalent organic group having 1 to 20 carbon atoms which may be represented by R⁷ include groups similar to those exemplified above as the organic groups for R¹ to R⁶, and the like.

R⁷ represents preferably a hydrogen atom.

As n, 1 and 2 are preferred, and 1 is more preferred.

Examples of the group (I) include groups represented by the following formulae (1-1) to (1-12) (hereinafter, may be also referred to as “groups (I-1) to (I-12)”) and the like.

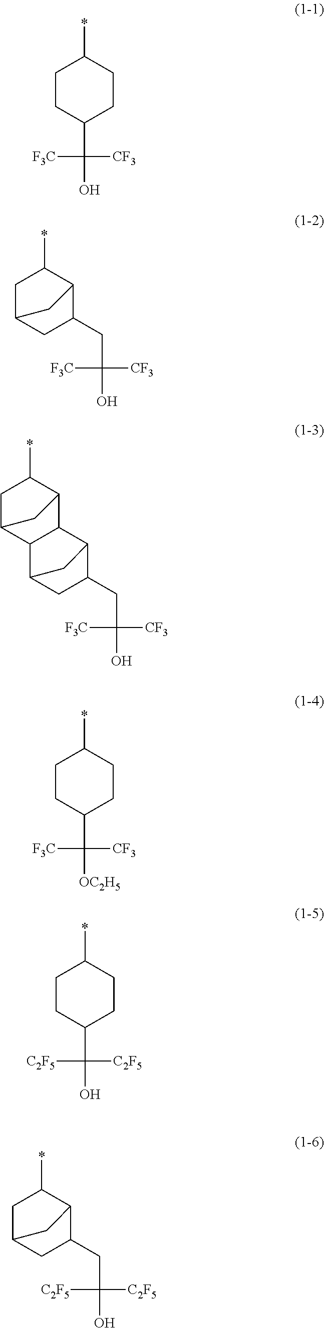

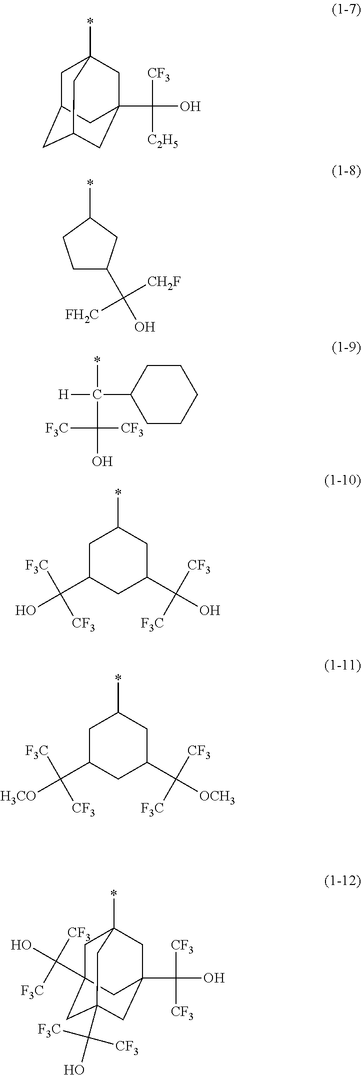

In the above formulae (1-1) to (1-12), * denotes a bonding site to a moiety other than the group (I) in the structural unit (I).

Of these, the groups (I-1) to (I-3) and (I-10) are preferred.

Examples of the structural unit (I) include a structural unit represented by the following formula (i-1) (hereinafter, may be also referred to as “structural unit (I-1)”), a structural unit represented by the following formula (i-2) (hereinafter, may be also referred to as “structural unit (I-2)”), and the like.

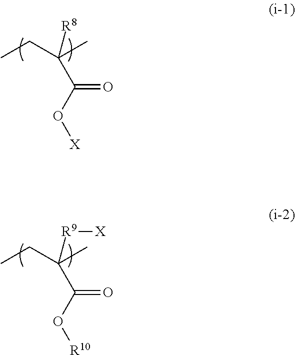

In the above formulae (i-1) and (i-2), X represents the group (I).

In the above formula (i-1), R⁸ represents a hydrogen atom, a fluorine atom, a methyl group or a trifluoromethyl group.

In the above formula (i-2), R⁹ represents a single bond, —O— or a divalent organic group having 1 to 20 carbon atoms; R¹⁰ represents a hydrogen atom or a monovalent organic group having 1 to 20 carbon atoms.

R⁸ represents, in light of the degree of copolymerization of the monomer that gives the structural unit (I-1), preferably a hydrogen atom or a methyl group, and more preferably a methyl group.

It is preferred that R⁹ represents —O—.

R¹⁰ represents preferably a hydrogen atom or a monovalent hydrocarbon group having 1 to 20 carbon atoms, and more preferably an alkyl group having 1 to 20 carbon atoms, an alicyclic saturated hydrocarbon group having 3 to 20 carbon atoms or an aralkyl group having 9 to 20 carbon atoms.

The lower limit of the proportion of the structural unit (I) contained with respect to the total structural units constituting the polymer component (A) is preferably 1 mol %, more preferably 5 mol %, still more preferably 8 mol %, particularly preferably 12 mol %, and further particularly preferably 15 mol %. The upper limit of the proportion of the structural unit (I) is preferably 80 mol %, more preferably 50 mol %, still more preferably 40 mol %, particularly preferably 30 mol %, and further particularly preferably 25 mol %. When the proportion of the structural unit (I) contained falls within the above range, the radiation-sensitive resin composition enables the LWR performance, etc. to be more improved.

Structural Unit (II)

The structural unit (II) includes a hydroxyl group bonded to an aromatic ring.

Examples of the aromatic ring include a benzene ring, a naphthalene ring, an anthracene ring, a phenanthrene ring, a tetracene ring, a pentacene ring and the like. Of these, a benzene ring and a naphthalene ring are preferred, and a benzene ring is more preferred.

The group that includes the hydroxyl group bonded to the aromatic ring (hereinafter, may be also referred to as “group (II)”) is exemplified by groups represented by the following formulae, and the like.

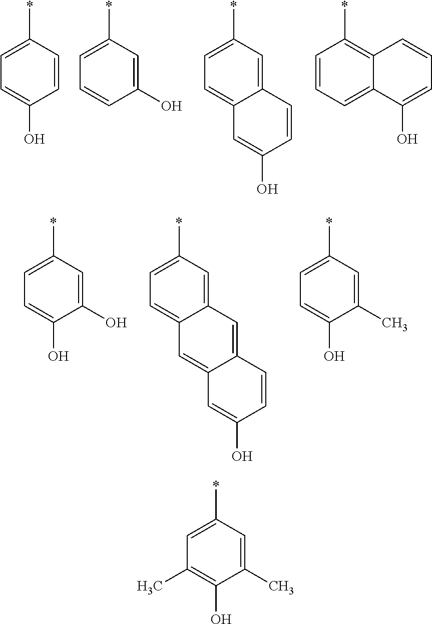

Exemplary structural unit (II) includes a structural unit represented by the following formula (ii-1) (hereinafter, may be also referred to as “structural unit (II-1)”), and the like.

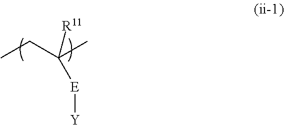

In the above formula (ii-1), R¹¹ represents a hydrogen atom, a fluorine atom, a methyl group or a trifluoromethyl group; E represents a single bond, —O—, —CO—, —COO—or —CONH—; and Y represents the group (II).

R¹¹ represents, in light of the degree of copolymerization of the monomer that gives the structural unit (II-1), preferably a hydrogen atom or a methyl group.

E represents preferably a single bond or —COO—.

The lower limit of the proportion of the structural unit (II) contained with respect to the total structural units constituting the polymer component (A) is preferably 10 mol %, more preferably 20 mol %, still more preferably 30 mol %, and particularly preferably 35 mol %. The upper limit of the proportion of the structural unit (II) is preferably 80 mol %, more preferably 70 mol %, still more preferably 60 mol %, and particularly preferably 55 mol %. When the proportion of the structural unit (II) contained falls within the above range, the radiation-sensitive resin composition enables the LWR performance to be more improved.

### Structural Unit (III)

The structural unit (III) includes an acid-labile group. The “acid-labile group” as referred to herein means a group that substitutes for a hydrogen atom of a carboxy group, a hydroxy group or the like and is dissociated by an action of an acid. The radiation-sensitive resin composition has more enhanced sensitivity due to including the polymer component (A) having the structural unit (III), and consequently, more improvements of the LWR performance, etc. are enabled.

Examples of the structural unit (III) include a structural unit represented by the following formula (iii-1) (hereinafter, may be also referred to as “structural unit (III-1)”), a structural unit represented by the following formula (iii-2) (hereinafter, may be also referred to as “structural unit (III-2)”), and the like.

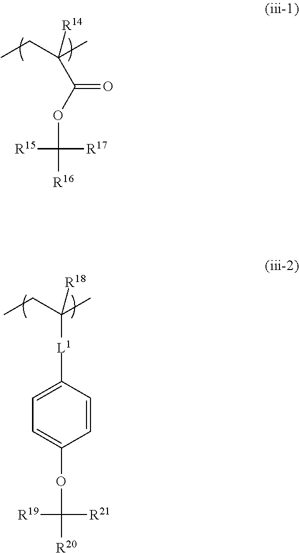

In the above formula (iii-1), R¹⁴ represents a hydrogen atom, a fluorine atom, a methyl group or a trifluoromethyl group; R¹⁵ represents a monovalent hydrocarbon group having 1 to 20 carbon atoms; R¹⁶ and R¹⁷ each independently represent a monovalent hydrocarbon group having 1 to 20 carbon atoms, or R¹⁶ and R¹⁷ taken together represent an alicyclic structure having 3 to 20 carbon atoms together with the carbon atom to which R¹⁶ and R¹⁷ bond.

In the above formula (iii-2), R¹⁸ represents a hydrogen atom or a methyl group; L¹ represents a single bond, —CCOO—or —CONH—; R¹⁹, R²⁰ and R²¹ each independently represent a hydrogen atom, a monovalent hydrocarbon group having 1 to 20 carbon atoms or a monovalent oxyhydrocarbon group having 1 to 20 carbon atoms.

R¹⁴ represents, in light of the degree of copolymerization of the monomer that gives the structural unit (III-1), preferably a hydrogen atom or a methyl group, and more preferably a methyl group.

R¹⁸ represents, in light of the degree of copolymerization of the monomer that gives the structural unit (III-2), preferably a hydrogen atom.

The monovalent hydrocarbon group having 1 to 20 carbon atoms which may be represented by R¹⁵ to R¹⁷ and R¹⁹ to R²¹ is exemplified by a monovalent chain hydrocarbon group having 1 to 20 carbon atoms, a monovalent alicyclic hydrocarbon group having 3 to 20 carbon atoms, a monovalent aromatic hydrocarbon group having 6 to 20 carbon atoms, and the like.

Examples of the monovalent chain hydrocarbon group having 1 to 20 carbon atoms include:

alkyl groups such as a methyl group, an ethyl group, a n-propyl group, an i-propyl group, a n-butyl group, an i-butyl group, a sec-butyl group, a t-butyl group and a pentyl group;

alkenyl groups such as an ethenyl group, a propenyl group, a butenyl group and a pentenyl group;

alkynyl groups such as an ethynyl group, a propynyl group, a butynyl group and a pentynyl group; and the like.

Examples of the monovalent alicyclic hydrocarbon group having 3 to 20 carbon atoms include:

monocyclic alicyclic saturated hydrocarbon groups such as a cyclopropyl group, a cyclobutyl group, a cyclopentyl group and a cyclohexyl group;

polycyclic alicyclic saturated hydrocarbon groups such as a norbornyl group, an adamantyl group, a tricyclodecyl group and a tetracyclododecyl group;

monocyclic alicyclic unsaturated hydrocarbon groups such as a cyclopropenyl group, a cyclobutenyl group, a cyclopentenyl group and a cyclohexenyl group;

polycyclic alicyclic saturated hydrocarbon groups such as a norbornenyl group and a tricyclodecenyl group; and the like.

Examples of the monovalent aromatic hydrocarbon group having 6 to 20 carbon atoms include:

aryl groups such as a phenyl group, a tolyl group, a xylyl group, a naphthyl group and an anthryl group;

aralkyl groups such as a benzyl group, a phenethyl group, a naphthylmethyl group and an anthrylmethyl group; and the like.

Examples of the alicyclic structure having 3 to 20 carbon atoms which may be taken together represented by R¹⁶ and R¹⁷ together with the carbon atom to which R¹⁶ and R¹⁷ bond include:

monocyclic alicyclic structures such as a cyclopropane structure, a cyclobutane structure, a cyclopentane structure, a cyclohexane structure, a cycloheptane structure and a cyclooctane structure;

polycyclic alicyclic structures such as a norbornane structure, an adamantane structure, a tricyclodecane structure and a tetracyclododecane structure; and the like.

Examples of the monovalent oxyhydrocarbon group having 1 to 20 carbon atoms which may be represented by R¹⁹, R²° and R²¹ include groups obtained by incorporating an oxygen atom at the end on the atomic bonding side of the monovalent hydrocarbon group having 1 to 20 carbon atoms exemplified in connection with R¹⁵ to R¹⁷ and R¹⁹ to R²¹, and the like.

As R¹⁹, R²⁰ and R²¹, the chain hydrocarbon group and the cycloalkyloxy group are preferred.

As the structural unit (III-1), structural units represented by the following formulae (iii-1-1) to (iii-1-7) (hereinafter, may be also referred to as “structural units (III-1-1) to (III-1-7)”) are preferred.

As the structural unit (III-2), a structural unit represented by the following formula (iii-2-1) (hereinafter, may be also referred to as “structural unit (III-2-1)”) is preferred.

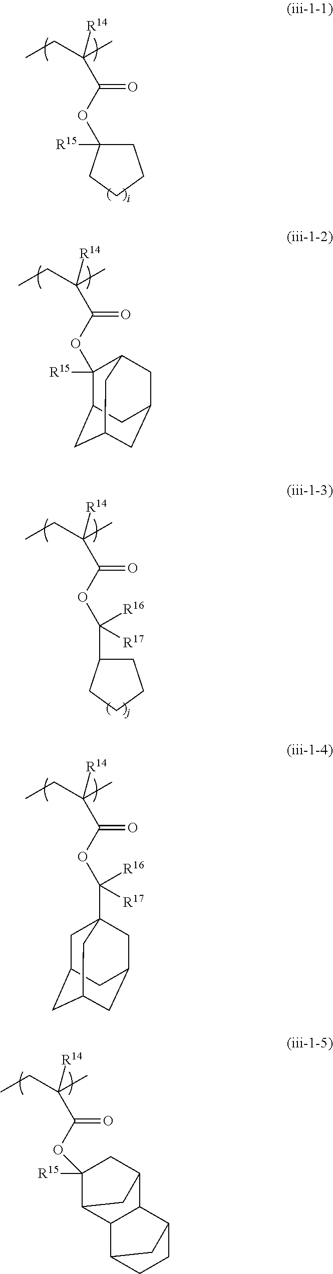

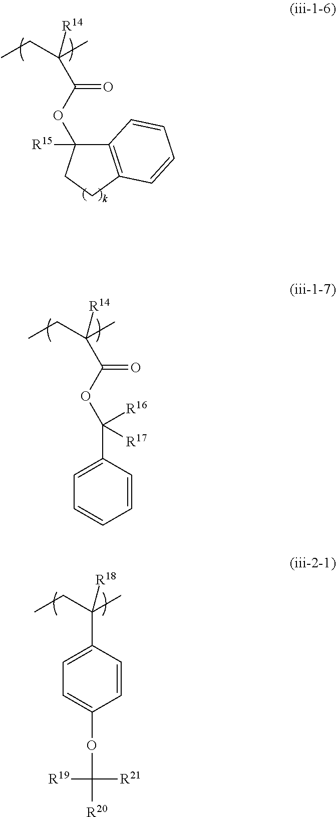

In the above formulae (iii-1-1) to (iii-1-7), R¹⁴ to R¹⁷ are as defined in the above formula (iii-1); and i, j and k are each independently an integer of 1 to 4. A part or all of hydrogen atoms on the cycloalkane ring in the above formula (iii-1-3) may be substituted with an alkyl group having 1 to 10 carbon atoms.

In the above formula (iii-2-1), R¹⁸ to R²¹ are as defined in the above formula (iii-2).

As the structural unit (III-1), the structural units (III-1-1) to (III-1-3) and (III-1-5) to (III-1-7) are preferred. As the structural unit (III-2), the structural unit (III-2-1) is preferred.

Examples of the structural unit (III-1) include structural units represented by the following formulae, and the like.

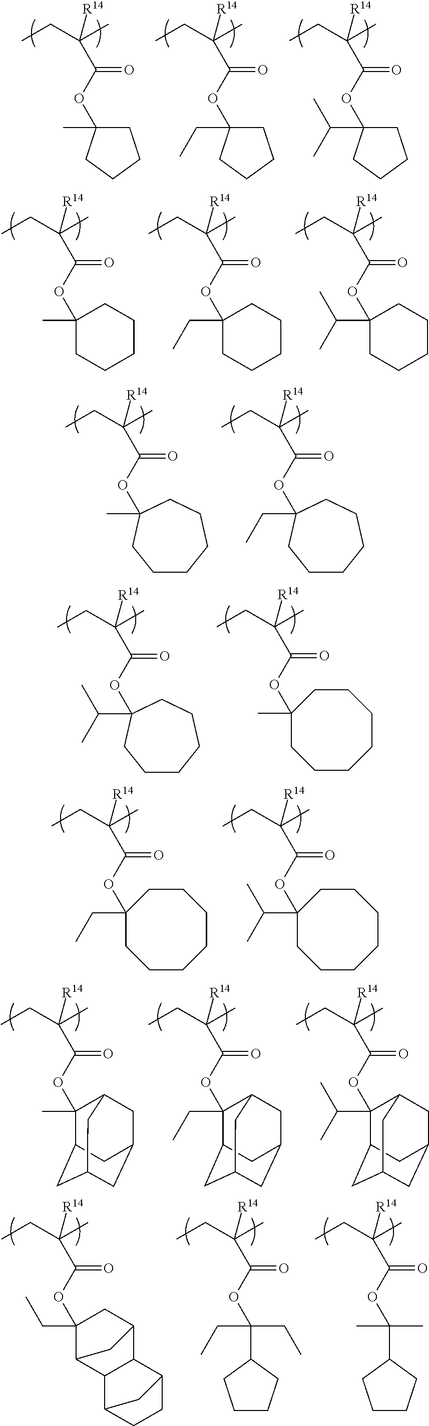

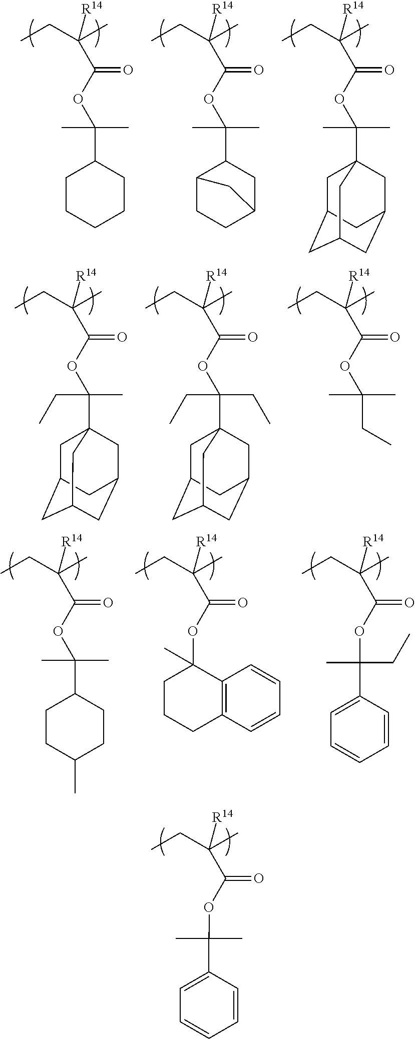

In the above formulae, R¹⁴ is as defined in the above formula (iii-1).

As the structural unit (III-1), a structural unit derived from t-alkyl (meth)acrylate, a structural unit derived from 2-alkyl-2-adamantyl (meth)acrylate, a structural unit derived from 1-alkyl-1-cyclopentyl (meth)acrylate, a structural unit derived from 2-(4-methylcyclohexan-1-yl)propan-1-yl (meth)acrylate, a structural unit derived from 2-alkyl-2-tetracyclododecanyl (meth)acrylate, a structural unit derived from 1-alkyl-2,3-benzocyclohexan-1-yl (meth)acrylate, and a structural unit derived from 2-phenylalkan-2-yl (meth)acrylate are preferred.

Examples of the structural unit (III-2) include structural units represented by the following formulae, and the like.

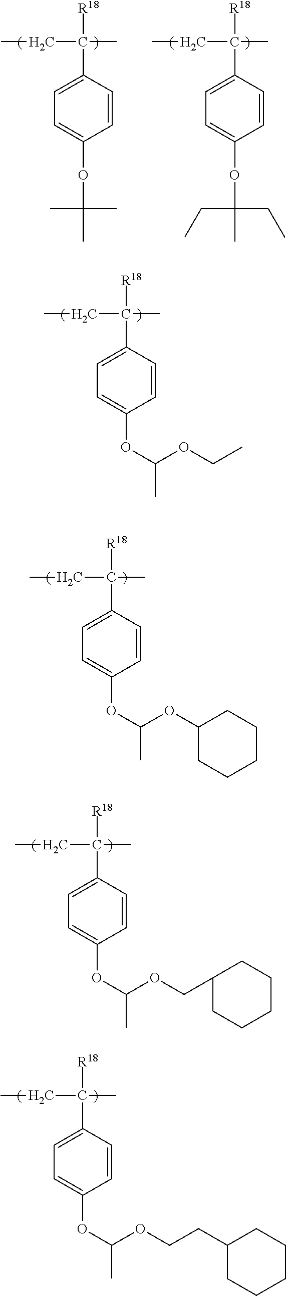

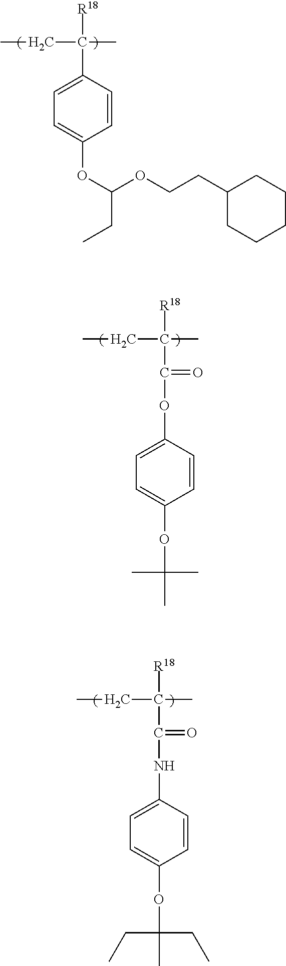

In the above formulae, R¹⁸ is as defined in the above formula (iii-2).

As the structural unit (III-2), a structural unit derived from p-(1-ethoxyethoxy)stryrene is preferred.

The lower limit of the proportion of the structural unit (III) contained is preferably 20 mol %, more preferably 30 mol %, still more preferably 35 mol %, and particularly preferably 40 mol %. The upper limit of the proportion of the structural unit (III) contained is preferably 80 mol %, more preferably 70 mol %, still more preferably 65 mol %, and particularly preferably 60 mol %. When the proportion of the structural unit (III) contained falls within the above range, the radiation-sensitive resin composition enables the LWR performance, etc. to be more improved.

Structural Unit (IV)

The structural unit (IV) includes a lactone structure, a cyclic carbonate structure, a sultone structure or a combination thereof. The polymer component (A) further having the structural unit (IV) enables the solubility thereof in the developer solution to be more improved, and consequently, the radiation-sensitive resin composition enables the LWR performance, etc. to be more improved. In addition, the adhesiveness between the substrate and the resist pattern formed from the radiation-sensitive resin composition can be improved.

Examples of the structural unit (IV) include structural units represented by the following formulae, and the like.

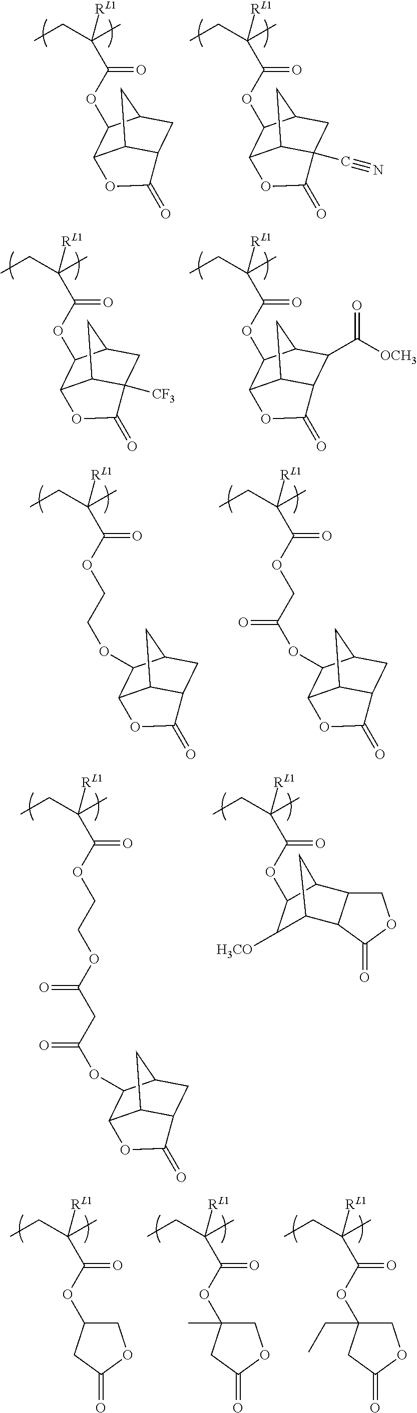

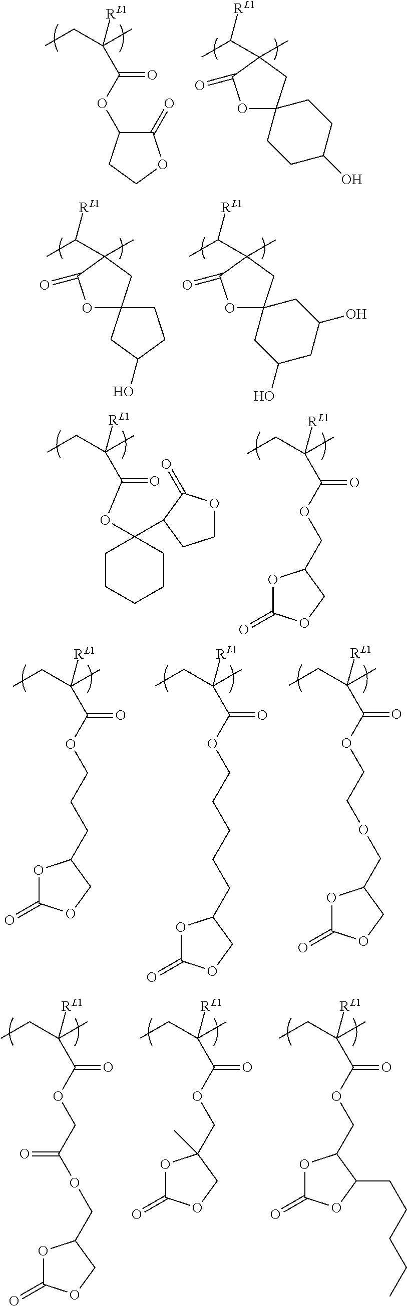

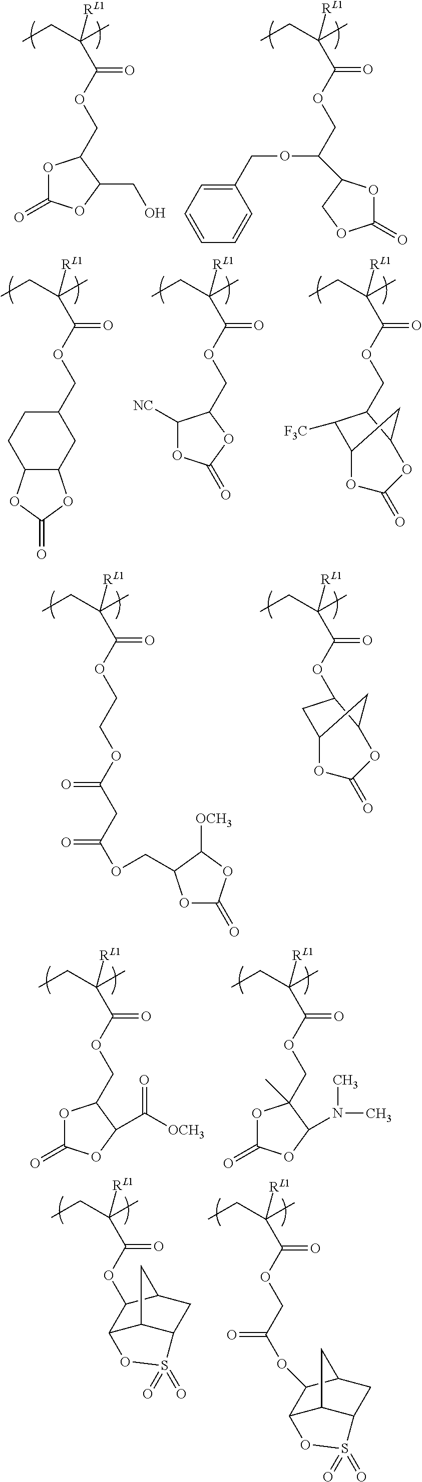

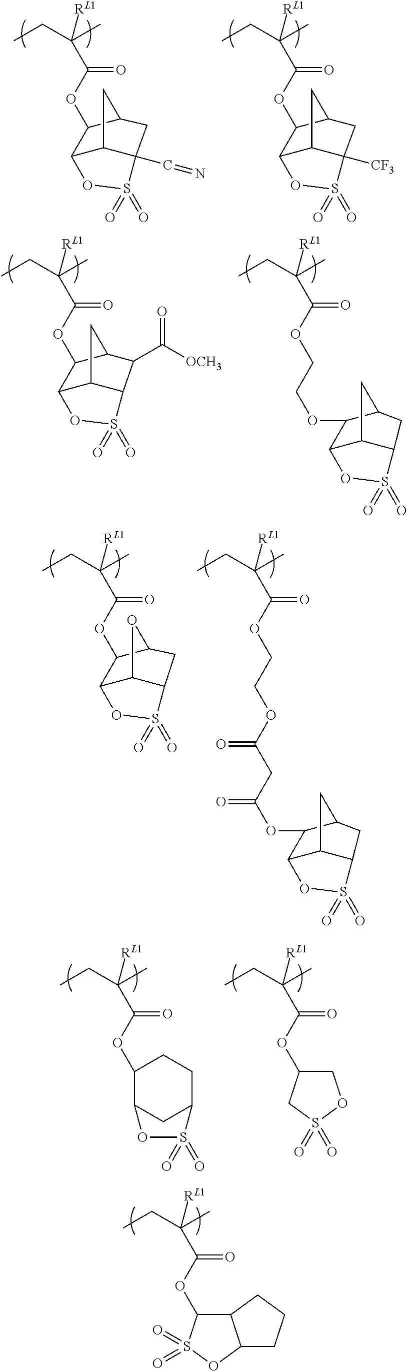

In the above formulae, R^{L1} represents a hydrogen atom, a fluorine atom, a methyl group or a trifluoromethyl group

As the structural unit (IV), the structural unit that includes a lactone structure is preferred, and the structural unit that includes a norbornanelactone structure and the structural unit that includes a γ-butyrolactone structure are more preferred.

In the case in which the polymer component (A) has the structural unit (IV), the lower limit of the proportion of the structural unit (IV) contained with respect to the total structural units constituting the polymer component (A) is preferably 1 mol %, more preferably 3 mol %, and still more preferably 5 mol %. The upper limit of the proportion of the structural unit (IV) is preferably 70 mol %, more preferably 30 mol %, and still more preferably 15 mol %. When the proportion of the structural unit (IV) contained falls within the above range, the radiation-sensitive resin composition enables the LWR performance, etc. to be further improved. In addition, the adhesiveness of the resist pattern to the substrate can be more improved.

Structural Unit (V)

The structural unit (V) includes an alcoholic hydroxyl group. The polymer component (A) further having the structural unit (V) enables the solubility thereof in the developer solution to be more improved, and consequently, the radiation-sensitive resin composition enables the LWR performance, etc. to be more improved. In addition, the adhesiveness between the substrate and the resist pattern formed from the radiation-sensitive resin composition can be improved.

Examples of the structural unit (V) include structural units represented by the following formulae, and the like.

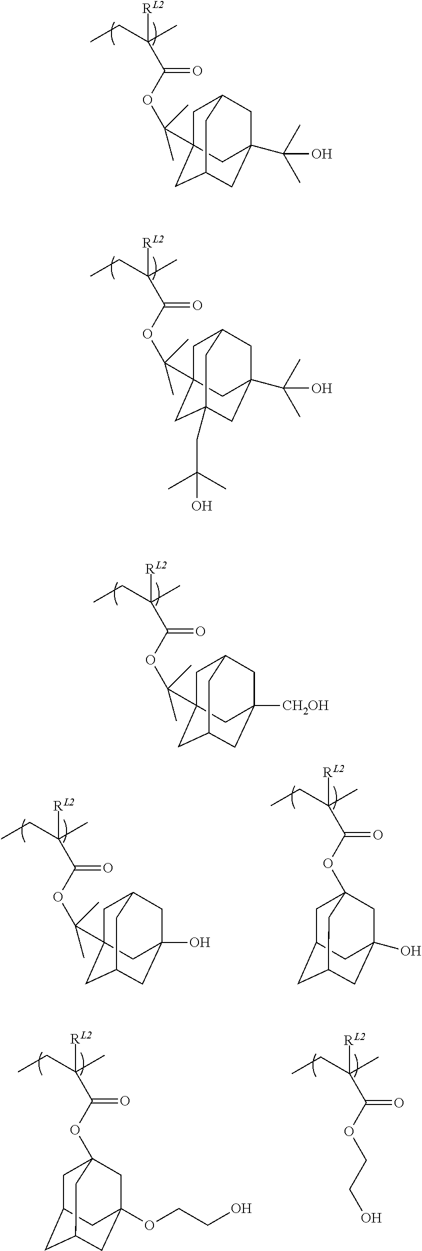

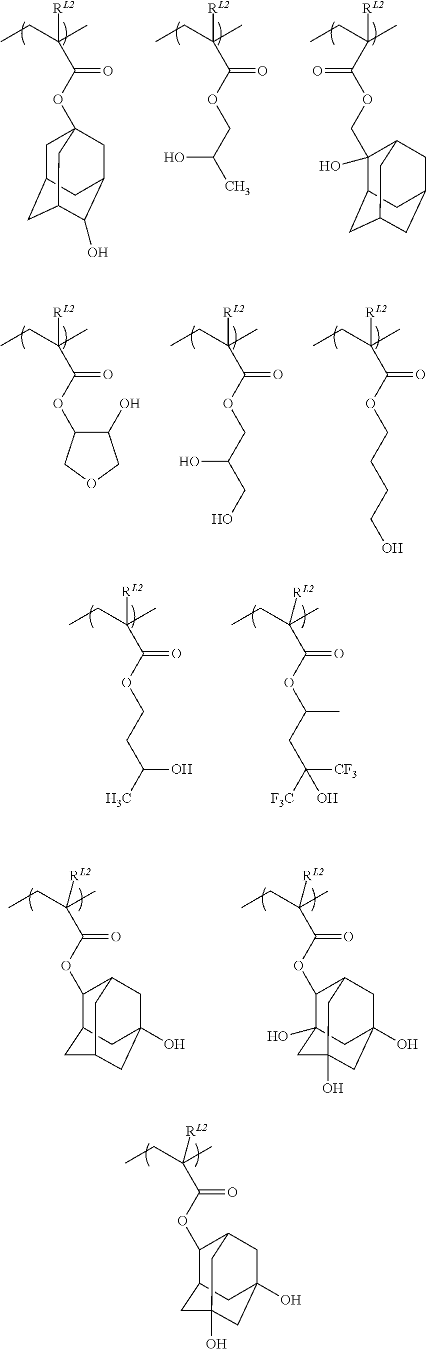

In the above formulae, R^{L2} represents a hydrogen atom, a fluorine atom, a methyl group or a trifluoromethyl group.

As the structural unit (V), a structural unit derived from 3-hydroxyadamantane-1-yl (meth)acrylate is preferred.

In the case in which the polymer component (A) has the structural unit (V), the lower limit of the proportion of the structural unit (V) contained with respect to the total structural units constituting the polymer component (A) is preferably 1 mol %, and more preferably 3 mol %. The upper limit of the proportion of the structural unit (V) contained is preferably 30 mol %, and more preferably 10 mol %.

Other Structural Unit

The polymer component (A) may have other structural unit in addition to the structural units (I) to (V), in a single polymer or different polymers. Examples of the other structural unit include: structural units each including a cyano group, a nitro group or a sulfonamide group, such as a structural unit derived from 2-cyanomethyladamantane-2-yl (meth)acrylate; structural units each including a fluorine atom, such as a structural unit derived from 2,2,2-trifluoroethyl (meth)acrylate, and a structural unit derived from 1,1,1,3,3,3-hexafluoropropan-2-yl (meth)acrylate; structural units each including an acid-nonlabile hydrocarbon group, such as a structural unit derived from styrene, a structural unit derived from vinylnaphthalene, and a structural unit derived from n-pentyl (meth)acrylate; and the like.

In the case in which the polymer component (A) has the other structural unit, the lower limit of the proportion of the other structural unit contained is preferably 1 mol %, and more preferably 3 mol %. The upper limit of the proportion of the other structural unit contained is preferably 30 mol %, and more preferably 10 mol %.

The lower limit of the content of the polymer component (A) in terms of solid content equivalent is preferably 50% by mass, more preferably 70% by mass, and still more preferably 80% by mass. The upper limit of the content is preferably 99% by mass, more preferably 98% by mass, and still more preferably 95% by mass. The term “solid content equivalent” as referred to herein means a proportion with respect to the total solid content in the radiation-sensitive resin composition, and the term “total solid content in the radiation-sensitive resin composition” as referred to herein means a sum of components other than the solvent (D).

### Synthesis Procedure of Polymer Component (A)

The polymer constituting the polymer component (A) may be synthesized, for example, by polymerization of a monomer that gives each structural unit using a radical polymerization initiator, etc., in an appropriate solvent.

Examples of the radical polymerization initiator include: azo-based radical initiators such as azobisisobutyronitrile (AIBN), 2,2′-azobis(4-methoxy-2,4-dimethylvaleronitrile), 2,2′-azobis(2-cyclopropylpropionitrile), 2,2′-azobis(2,4-dimethylvaleronitrile) and dimethyl 2,2′-azobisisobutyrate; peroxide-based radical initiators such as benzoyl peroxide, t-butyl hydroperoxide and cumene hydroperoxide; and the like. Of these, AIBN and dimethyl 2,2′-azobisisobutyrate are preferred, and AIBN is more preferred. These radical polymerization initiators may be used either alone, or as a mixture of two or more types thereof.

Examples of the solvent for use in the polymerization include:

alkanes such as n-pentane, n-hexane, n-heptane, n-octane, n-nonane and n-decane;

cycloalkanes such as cyclohexane, cycloheptane, cyclooctane, decalin and norbornane;

aromatic hydrocarbons such as benzene, toluene, xylene, ethylbenzene and cumene;

halogenated hydrocarbons such as chlorobutanes, bromohexanes, dichloroethanes, hexamethylene dibromide and chlorobenzene;

saturated carboxylic acid esters such as ethyl acetate, n-butyl acetate, i-butyl acetate and methyl propionate;

ketones such as acetone, butanone, 4-methyl-2-pentanone and 2-heptanone;

ethers such as tetrahydrofuran, dimethoxyethanes and diethoxyethanes;

alcohols such as methanol, ethanol, 1-propanol, 2-propanol and 4-methyl-2-pentanol; and the like. These solvents for use in the polymerization may be used alone, or two or more types thereof may be used in combination.

The lower limit of the reaction temperature in the polymerization is preferably 40° C., and more preferably 50° C. The upper limit of the reaction temperature is preferably 150° C., and more preferably 120° C. The lower limit of the of the reaction time in the polymerization is preferably 1 hr, and more preferably 2 hrs. The upper limit of the reaction time is preferably 48 hrs, and more preferably 24 hrs.

The lower limit of polystyrene equivalent weight average molecular weight (Mw) of the polymer component (A) as determined by gel permeation chromatography (GPC) is preferably 1,000, more preferably 2,000, still more preferably 3,000, and particularly preferably 5,000. The upper limit of the Mw is preferably 50,000, more preferably 30,000, still more preferably 20,000, and particularly preferably 10,000. When the Mw of the polymer component (A) falls within the above range, coating characteristics of the radiation-sensitive resin composition can be improved, and consequently, more improvements of the LWR performance, etc. are enabled.

The upper limit of a ratio (Mw/Mn) of the Mw to polystyrene equivalent number average molecular weight (Mn) of the polymer component (A) as determined by GPC is preferably 5, more preferably 3, still more preferably 2, and particularly preferably 1.7. The lower limit of the ratio is typically 1, and preferably 1.3.

The Mw and the Mn of the polymer as referred to herein are values determined by using GPC under the following conditions.

GPC columns: Tosoh Corporation, “G2000HXL”×2; “G3000HXL”×1; and “G4000HXL”×1

column temperature: 40° C.

elution solvent: tetrahydrofuran (Wako Pure Chemical Industries, Ltd.)

flow rate: 1.0 mL/min

sample concentration: 1.0% by mass

amount of injected sample: 100 μL

detector: differential refractometer

standard substance: mono-dispersed polystyrene

### (B) Acid Generating Component

The acid generating component (B) includes the acid generating agent (B1) and the acid generating agent (B2). The acid generating component (B) may include other acid generating agent in addition to the acid generating agent (B1) and the acid generating agent (B2). The acid generating component (B) generates an acid upon the exposure. The acid thus generated allows the acid-labile group included in the polymer component (A) or the like to be dissociated, thereby generating a carboxy group, a hydroxy group, etc. As a result, the solubility of the polymer component (A) and the like in the developer solution changes, and thus formation of a resist pattern from the radiation-sensitive resin composition of the embodiment of the present invention is enabled.

### (B1) Acid Generating Agent

The acid generating agent (B1) generates a sulfonic acid (hereinafter, may be also referred to as “sulfonic acid (I)”) including: a carbon atom that is adjacent to a sulfo group; and a fluorine atom bonded to the carbon atom, or a monovalent fluorinated hydrocarbon group bonded to the carbon atom. The sulfonic acid (I) has, for example, a group represented by the following formula (A).

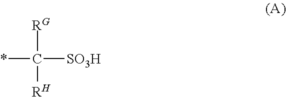

In the above formula (A), R^{G} and R^{H} each independently represent a fluorine atom or a monovalent fluorinated hydrocarbon group having 1 to 20 carbon atoms.

Examples of the fluorinated hydrocarbon group having 1 to 20 carbon atoms which may be represented by R^{G} and R^{H} include groups obtained by substituting with a fluorine atom, a part or all of hydrogen atoms included in the hydrocarbon group exemplified in connection with R¹ to R⁷, and the like.

As R^{G} and R^{H}, a fluorine atom and a perfluoroalkyl group are preferred, a fluorine atom and a trifluoromethyl group are more preferred, and a fluorine atom is still more preferred.

The sulfonic acid (I) is exemplified by a sulfonic acid represented by the following formula (3), and the like.

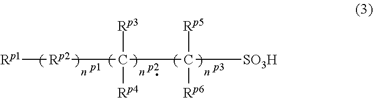

In the above formula (3), R^{p1} represents a monovalent group that includes a ring structure having no less than 6 ring atoms; R^{p2} represents a divalent linking group; R^{p3} and R^{p4} each independently represent a hydrogen atom, a fluorine atom, a monovalent hydrocarbon group having 1 to 20 carbon atoms or a monovalent fluorinated hydrocarbon group having 1 to 20 carbon atoms; R^{p5} and R^{p6} each independently represent a fluorine atom or a monovalent fluorinated hydrocarbon group having 1 to 20 carbon atoms; n^{p1} is an integer of 0 to 10; n^{p2} is an integer of 0 to 10; n^{p3} is an integer of 1 to 10, wherein n^{p1}+n^{p2}+n^{p3} is no greater than 30, and in a case in which n^{p1} is no less than 2, a plurality of R^{p2}s may be identical or different, in a case in which n^{p2} is no less than 2, a plurality of R^{p3}s may be identical or different, and a plurality of R^{p4}s may be identical or different, and in a case in which n^{p3} is no less than 2, a plurality of R^{p5}s may be identical or different, and a plurality of R^{p6}s may be identical or different.

The monovalent group that includes a ring structure having no less than 6 ring atoms represented by R^{p1} is exemplified by a monovalent group that includes an alicyclic structure having no less than 6 ring atoms, a monovalent group that includes an aliphatic heterocyclic structure having no less than 6 ring atoms, a monovalent group that includes an aromatic ring structure having no less than 6 ring atoms, a monovalent group that includes an aromatic heterocyclic structure having no less than 6 ring atoms, and the like.

Examples of the alicyclic structure having no less than 6 ring atoms include:

monocyclic saturated alicyclic structures such as a cyclohexane structure, a cycloheptane structure, a cyclooctane structure, a cyclononane structure, a cyclodecane structure and a cyclododecane structure;

monocyclic unsaturated alicyclic structures such as a cyclohexene structure, a cycloheptene structure, a cyclooctene structure and a cyclodecenc structure;

polycyclic saturated alicyclic structures such as a norbornane structure, an adamantane structure, a tricyclodecane structure and a tetracyclododecane structure;

polycyclic unsaturated alicyclic structures such as a norbornene structure and a tricyclodecene structure; and the like.

Examples of the aliphatic heterocyclic structure having no less than 6 ring atoms include:

lactone structures such as a hexanolactone structure and a norbornanelactonc structure;

sultone structures such as a hexanosultone structure and a norbornanesultone structure;

oxygen atom-containing heterocyclic structures such as an oxacycloheptane structure and an oxanorbornane structure;

nitrogen atom-containing heterocyclic structures such as an azacyclohexane structure, a diazabicyclooctane structure and an azadecalin structure;

sulfur atom-containing heterocyclic structures such as a thiacyclohexane structure and a thianorbornane structure; and the like.

Examples of the aromatic ring structure having no less than 6 ring atoms include a benzene structure, a naphthalene structure, a phenanthrene structure, an anthracene structure, and the like.

Examples of the aromatic heterocyclic structure having no less than 6 ring atoms include:

oxygen atom-containing heterocyclic structures such as a pyran structure, a benzofuran structure and a benzopyran structure;

nitrogen atom-containing heterocyclic structures such as a pyridine structure, a pyrimidine structure and an indole structure; and the like.

The lower limit of the number of ring atoms of the ring structure in R^{p1} is preferably 7, more preferably 8, still more preferably 9, and particularly preferably 10. The upper limit of the number of ring atoms is preferably 15, more preferably 14, still more preferably 13, and particularly preferably 12. When the number of the ring atoms falls within the above range, the diffusion length of the acid may be further properly reduced, and consequently, the radiation-sensitive resin composition enables the LWR performance, etc. to be more improved.

A part or all of hydrogen atoms included in the ring structure in R^{p1} may be substituted with a substituent. Examples of the substituent include halogen atoms such as a fluorine atom, a chlorine atom, a bromine atom and an iodine atom, a hydroxy group, a carboxy group, a cyano group, a nitro group, an alkoxy group, an alkoxycarbonyl group, an alkoxycarbonyloxy group, an acyl group, an acyloxy group and the like. Of these, a hydroxy group is preferred.

R^{p1} represents preferably a monovalent group that includes an alicyclic structure having no less than 6 ring atoms or a monovalent group that includes an aliphatic heterocyclic structure having no less than 6 ring atoms, more preferably a monovalent group that includes an alicyclic structure having no less than 9 ring atoms, or a monovalent group that includes an aliphatic heterocyclic structure having no less than 9 ring atoms, still more preferably an adamantyl group, a hydroxyadamantyl group, a norbornanelactone-yl group, a norbornanesultone-yl group or a 5-oxo-4-oxatricyclo[4.3.1.1^{3,8}]undecanyl group, and particularly preferably an adamantyl group.

Examples of the divalent linking group represented by R^{p2} include a carbonyl group, an ether group, a carbonyloxy group, a sulfide group, a thiocarbonyl group, a sulfonyl group, a divalent hydrocarbon group and the like. Of these, a carbonyloxy group, a sulfonyl group, an alkanediyl group and a divalent alicyclic saturated hydrocarbon group are preferred, a carbonyloxy group and a divalent alicyclic saturated hydrocarbon group are more preferred, a carbonyloxy group and a norbornanediyl group are still more preferred, and a carbonyloxy group is particularly preferred.

The monovalent hydrocarbon group having 1 to 20 carbon atoms which may be represented by R^{p3} and R^{p4}is exemplified by an alkyl group having 1 to 20 carbon atoms and the like; the monovalent fluorinated hydrocarbon group having 1 to 20 carbon atoms which may be represented by R^{p3} and R^{p4} is exemplified by a fluorinated alkyl group having 1 to 20 carbon atoms and the like; R^{p3} and R^{p4} each independently represent preferably a hydrogen atom, a fluorine atom or a fluorinated alkyl group, more preferably a fluorine atom or a perfluoroalkyl group, and still more preferably a fluorine atom or a trifluoromethyl group.

The monovalent fluorinated hydrocarbon group having 1 to 20 carbon atoms which may be represented by R^{p5} and R^{p6} is exemplified by a fluorinated alkyl group having 1 to 20 carbon atoms and the like; R^{p5} and R^{p6} each independently represent preferably a fluorine atom or a fluorinated alkyl group, more preferably a fluorine atom or a perfluoroalkyl group, still more preferably a fluorine atom or a trifluoromethyl group, and particularly preferably a fluorine atom.

In the above formula, n^{p1} referably an integer of 0 to 5, more preferably an integer of 0 to 3, still more preferably an integer of 0 to 2, and particularly preferably 0 or 1.

In the above formula, n^{p2} is preferably an integer of 0 to 5, more preferably an integer of 0 to 2, still more preferably 0 or 1, and particularly preferably 0.

The lower limit of n^{p3} is preferably 1, and more preferably 2. When n^{p3} is no less than 1, the strength of the acid generated from the compound (4-1) can be increased, and consequently, the radiation-sensitive resin composition enables the LWR performance, etc. to be more improved. The upper limit of n^{p3} is preferably 4, more preferably 3, and still more preferably 2.

The lower limit of (n^{p1}+n^{p2}+n^{p3}) and more preferably 2, and more preferably 4. The upper limit of (n^{p1}+n^{p2}+n^{p3}) is preferably 20, and more preferably 10.

The acid generating agent (B1) is exemplified by: an onium salt compound (hereinafter, may be also referred to as “compound (4-1)”) including a monovalent radiation-sensitive onium cation, and a sulfonate anion derived from the sulfo group of the sulfonic acid (I) by removing a proton; an azo compound (hereinafter, may be also referred to as “compound (4-2)”) in which two groups obtained by removing the hydrogen atom of the sulfo group in the sulfonic acid (I) are bonded to —(C═N₂)—; an N-sulfonylimideoxy compound (hereinafter, may be also referred to as “compound (4-3)”) in which a group obtained by removing the hydrogen atom from the sulfo group in the sulfonic acid (I) is bonded to a nitrogen atom in the disulfonylimide group; and the like.

Examples of the monovalent radiation-sensitive onium cation in the compound (4-1) include cations represented by the following formulae (Z-1) to (Z-3) (hereinafter, may be also referred to as “cations (Z-1) to (Z-3)”) and the like.

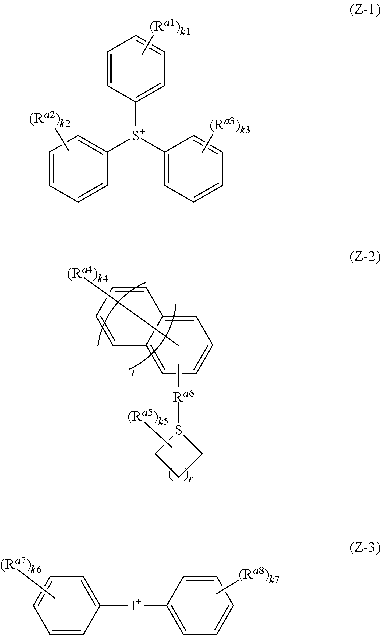

In the above formula (Z-1), R^{a1}, R^{a2} and R^{a3} each independently represent an alkyl group having 1 to 12 carbon atoms, an aromatic hydrocarbon group having 6 to 12 carbon atoms, —OSO₂—R^{P} or —SO₂—R^{Q}, or a ring structure taken together represented by at least two of these groups, wherein R^{P} and R^{Q}, each independently represent an alkyl group having 1 to 12 carbon atoms, an alicyclic hydrocarbon group having 5 to 25 carbon atoms or an aromatic hydrocarbon group having 6 to 12 carbon atoms; and k1, k2 and k3 are each independently an integer of 0 to 5, wherein in a case in which there exist a plurality of R^{a1}s to R^{a3}s and R^{P}s and R^{Q}s, respectively, the plurality of R^{a1}s to R^{a3}s and R^{P}s and R^{Q}s may be each identical to or different from each other.

In the above formula (Z-2), R^{a4} represents an alkyl group having 1 to 8 carbon atoms or an alkoxy group having 1 to 8 carbon atoms, or an aromatic hydrocarbon group having 6 to 8 carbon atoms; k4 is an integer of 0 to 7; in a case in which there exist a plurality of R^{a4}s, the plurality of R^{a4}s may be identical or different, or the plurality of R^{a4}s may taken together represent a ring structure; R^{a5} represents an alkyl group having 1 to 7 carbon atoms, or an aromatic hydrocarbon group having 6 or 7 carbon atoms; k5 is an integer of 0 to 6; in a case in which there exist a plurality of R^{a5}s, the plurality of R^{a5}s may be identical or different, or the plurality of R^{a5}s may taken together represent a ring structure; r is an integer of 0 to 3; R^{a6} represents a single bond or a divalent organic group having 1 to 20 carbon atoms; and t is an integer of 0 to 2.

In the above formula (Z-3), R^{a7} and R^{a8} each independently represent an alkyl group having 1 to 12 carbon atoms, an aromatic hydrocarbon group having 6 to 12 carbon atoms, —OSO₂-13 R^{R} or —SO₂-R^{S}, or a ring structure taken together represented by at least two of these groups, wherein R^{R} and R^{S} each independently represent an alkyl group having 1 to 12 carbon atoms, an alicyclic hydrocarbon group having 5 to 25 carbon atoms or an aromatic hydrocarbon group having 6 to 12 carbon atoms; k6 and k7 are each independently an integer of 0 to 5, wherein, in a case in which there exist a plurality of R^{a7}s, R^{a8}s, R^{R}s and R^{S}s, respectively, the plurality of R^{a7}s, R^{a8}s, R^{R}s and R^{S}s may be each identical to or different from each other.

Examples of the alkyl group which may be represented by R^{a1} to R^{a3}, R^{a4}, R^{a5}, R^{a7} and R^{a8} include:

linear alkyl groups such as a methyl group, an ethyl group, a n-propyl group and a n-butyl group;

branched alkyl groups such as an i-propyl group, an i-butyl group, a sec-butyl group and a t-butyl group; and the like.

Examples of the aromatic hydrocarbon group which may be represented by R^{a1} to R^{a3}, R^{a4} and R^{a5} include:

aryl groups such as a phenyl group, a tolyl group, a xylyl group, a mesityl group and a naphthyl group;

aralkyl groups such as a benzyl group and a phenethyl group; and the like.

Examples of the aromatic hydrocarbon group which may be represented by R^{a4} and R^{a5} include: a phenyl group, a tolyl group, a benzyl group and the like.

Examples of the divalent organic group which may be represented by R^{a6} include similar groups to those for L¹ in the above formula (1), and the like.

The hydrogen atoms included in the alkyl group and the aromatic hydrocarbon group which may be represented by R^{a1}, R^{a2}, R^{a3}, R^{P}, R^{Q}, R^{a4},R^{a5}, R^{R}, R^{S}, R^{a7} and R^{a8} in the above formulae (Z-1) to (Z-3) may be substituted with a halogen atom such as a fluorine atom, a chlorine atom, a bromine atom or an iodine atom, a hydroxy group, a carboxy group, a cyano group, a nitro group, an alkoxy group, an alkoxycarbonyl group, an alkoxycarbonyloxy group, an acyl group, an acyloxy group, or the like. Of these substituents, the halogen atom is preferred, and a fluorine atom is more preferred.

As R^{a1} to R^{a3}, R^{a4}, R^{a5}, R^{a7} and R^{a8}, the alkyl group unsubstituted, the fluorinated alkyl group, the monovalent aromatic hydrocarbon group unsubstituted, —OSO₂—R″ and —SO₂—R″ are preferred, the fluorinated alkyl group and the monovalent aromatic hydrocarbon group unsubstituted is more preferred, and the fluorinated alkyl group is still more preferred. R″ herein represents an unsubstituted monovalent alicyclic hydrocarbon group or an unsubstituted monovalent aromatic hydrocarbon group.

The hydrogen atoms included in the alicyclic hydrocarbon group which may be represented by R^{P} and R^{Q} in the above formula (Z-1), and R^{R} and R^{S} in the above formula (Z-3) may be substituted with a similar substituent to those for R^{a1} and the like described above.

In the formula (Z-1), k1, k2 and k3 are each preferably an integer of 0 to 2, more preferably 0 or 1, and still more preferably 0. In the formula (Z-2), k4 is preferably an integer of 0 to 2, more preferably 0 or 1, and still more preferably 1; k5 is preferably an integer of 0 to 2, more preferably 0 or 1, and still more preferably 0; r is preferably 2 or 3, and more preferably 2; t is preferably 0 or 1, and more preferably 0. In the formula (Z-3), k6 and k7 are preferably an integer of 0 to 2, more preferably 0 or 1, and still more preferably 0.

Of these, the monovalent radiation-sensitive onium cation is preferably a triphenylsulfonium cation, a tritolylsulfonium cation, a 4-butoxynaphthalene-1-yltetrahydrothiophenium cation, a 1-phenylcarbonyl-1-methylethan-1-yltetrahydrothiophenium cation or a di-4-t-butylphenyliodonium cation.

With respect to the acid generating agent (B1), examples of the compound (4-1) include compounds represented by the following formulae (4-1-1) to (4-1-19) (hereinafter, may be also referred to as “compound (4-1-1) to (4-1-19)”) and the like, and examples of the compound (4-2) include a compound represented by the following formula (4-2-1) (hereinafter, may be also referred to as “compound (4-2-1)”) and the like, and examples of the compound (4-3) include a compound represented by the following formula (4-3-1) (hereinafter, may be also referred to as “compound (4-3-1)”) and the like.

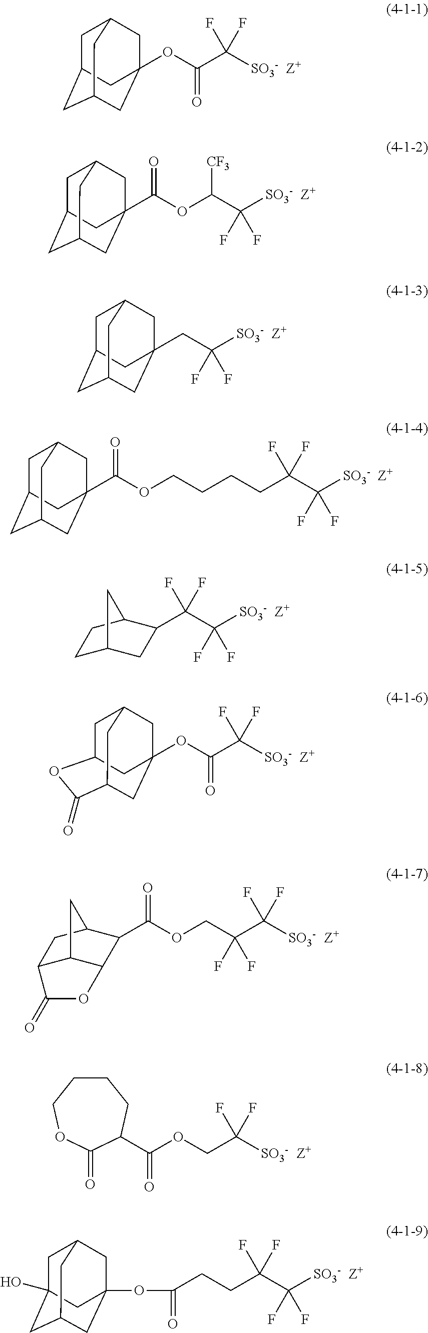

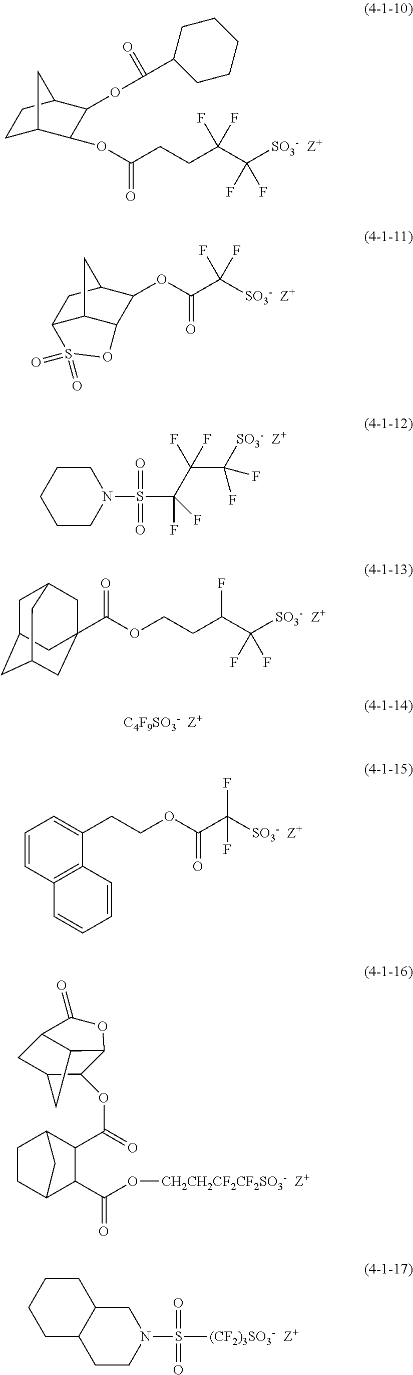

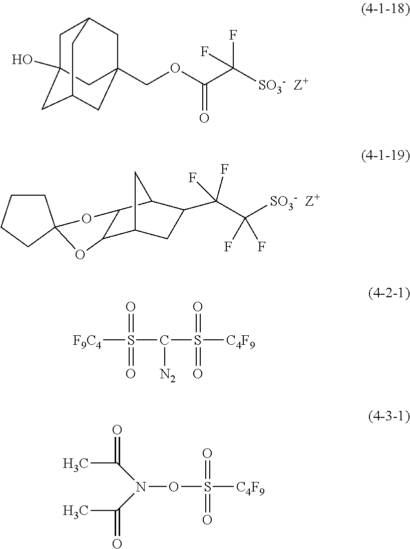

In the above formulae (4-1-1) to (4-1-19), Z⁺ represents a monovalent radiation-sensitive onium cation.

In addition, the compound (4-1) for the acid generating agent (B1) is exemplified by a compound that includes a monovalent radiation-sensitive onium cation and an anion represented by one of the following formulae, and the like.

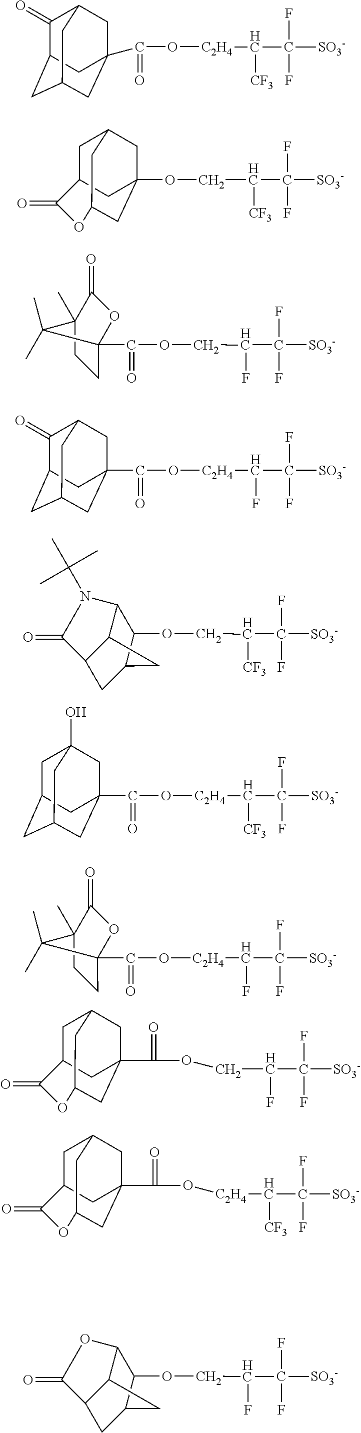

The lower limit of the content of the acid generating component (B1) with respect to an entirety of the acid generating agent (B) is preferably 10% by mass, more preferably 20% by mass, and still more preferably 30% by mass. The upper limit of the content of the acid generating component (B1) is preferably 80% by mass, more preferably 70% by mass, and still more preferably 60% by mass. When the content of the acid generating agent (B1) falls within the above range, the radiation-sensitive resin composition enables the LWR performance, etc. to be more improved. One, or two or more types of the acid generating agent (B1) may be used.

(B2) Acid Generating Agent

The acid generating agent (B2) generates a sulfonic acid (hereinafter, may be also referred to as “sulfonic acid (II)”) including: a carbon atom that is adjacent to a sulfo group; and a carbon atom that is adjacent to the carbon atom, wherein neither a fluorine atom nor a monovalent fluorinated hydrocarbon group is bonded to these carbon atoms; or a carboxylic acid (hereinafter, may be also referred to as “carboxylic acid (II)”) including: a carbon atom that is adjacent to a carboxy group; and a fluorine atom bonded to the carbon atom, or a monovalent fluorinated hydrocarbon group bonded to the carbon atom.

The sulfonic acid (II) is exemplified by a sulfonic acid represented by the following formula (2), and the like.

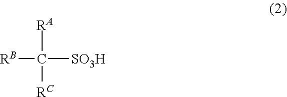

In the above formula (2), R^{A}, R^{B} and R^{C} each independently represent a hydrogen atom or a monovalent organic group having 1 to 20 carbon atoms, or at least two of R^{A}, R^{B} and R^{C} taken together represent an alicyclic structure having 3 to 20 ring atoms together with the carbon atom to which the at least two of R^{A}, R^{B} and R^{c} bond, wherein a carbon atom serves as a bonding site to the carbon atom that is adjacent to the sulfo group in the organic group, and neither a fluorine atom nor a fluorinated hydrocarbon group is bonded to the carbon atom, and at least one of R^{A}, R^{B} and R^{C} represents the organic group.

The monovalent organic group having 1 to 20 carbon atoms which may be represented by R^{A}, R^{B} and R^{C} is exemplified by, of the monovalent organic groups having 1 to 20 carbon atoms exemplified in connection with R¹ to R⁷ above, those in which a carbon atom serves as a bonding site to the carbon atom that is adjacent to the sulfo group, and neither a fluorine atom nor a fluorinated hydrocarbon group is bonded to the carbon atom, and the like. Of these, the monovalent hydrocarbon group having 1 to 20 carbon atoms is preferred, and the alkyl group and the alicyclic saturated hydrocarbon group are more preferred. A part or all of hydrogen atoms included in the hydrocarbon group, the alkyl group and the alicyclic saturated hydrocarbon group, may be substituted with a morpholino group, an oxo group (═0), a phenyloxy group, a phenyloxycarbonyl group, an alkoxy group having 1 to 8 carbon atoms, or the like. It is preferred that one or two of R^{A}, R^{B} and R^{C} represent(s) a hydrogen atom, and it is more preferred that two of these each represent a hydrogen atom. The alicyclic structure having 3 to 20 ring atoms which may be taken together represented by at least two of R^{A}, R^{B} and R^{C} is exemplified by a monocyclic alicyclic structure such as a cyclohexane structure, a polycyclic alicyclic structure such as a tetracyclododecane structure; and the like.

Examples of the carboxylic acid (II) include carboxylic acids in which a fluorine atom bonds to a carbon atom that is adjacent to a carboxy group, e.g., perfluoroalkanecarboxylic acids such as nonafluoro-n-butanecarboxylic acid and tridecafluoro-n-hexanecarboxylic acid perfluorocycloalkanecarboxylic acids such as nonafluorocyclopentanecarboxylic acid and undecafluorocyclohexanecarboxylic acid, and the like.

The acid generating agent (B2) is exemplified by: an onium salt compound (hereinafter, may be also referred to as “compound (5-1)”) including a monovalent radiation-sensitive onium cation, and an anion derived from the sulfo group of the sulfonic acid (II) by removing a proton; an onium salt compound (hereinafter, may be also referred to as “compound (5-2)”) including a monovalent radiation-sensitive onium cation, and an anion derived from the carboxy group of the carboxylic acid (II) by removing a proton; and the like. Examples of the monovalent radiation-sensitive onium cation include cations similar to those exemplified as the monovalent radiation-sensitive onium cation included in the compound (4-1), and the like.

With respect to the acid generating agent (B2), examples of the compound (5-1) include compounds represented by the following formulae (5-1-1) to (5-1-5) and the like, and examples of the compound (5-2) include compounds represented by the following formulae (5-2-1) and (5-2-2) (hereinafter, may be also referred to as “compounds (5-2-1) and (5-2-2)”) and the like.

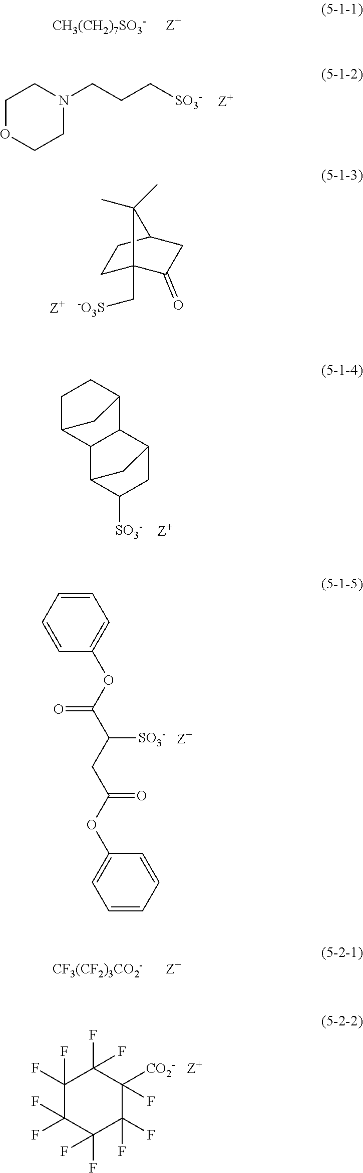

In the above formulae (5-1-1) to (5-1-5), (5-2-1) and (5-2-2), Z⁺ represents a monovalent radiation-sensitive onium cation.

In addition, the compound (5-2) for the acid generating agent (B2) is exemplified by a compound that includes a monovalent radiation-sensitive onium cation and an anion represented by one of the following formulae (A-1) to (A-53), and the like.

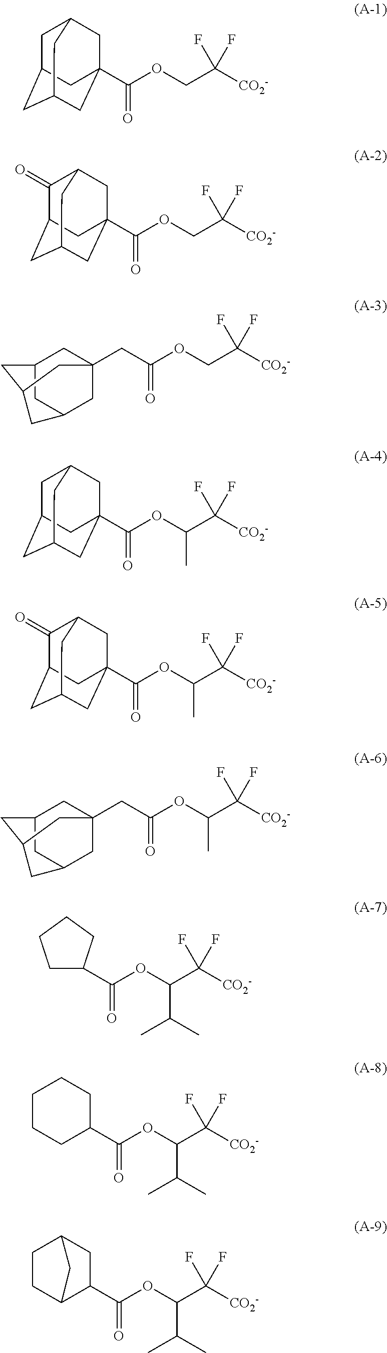

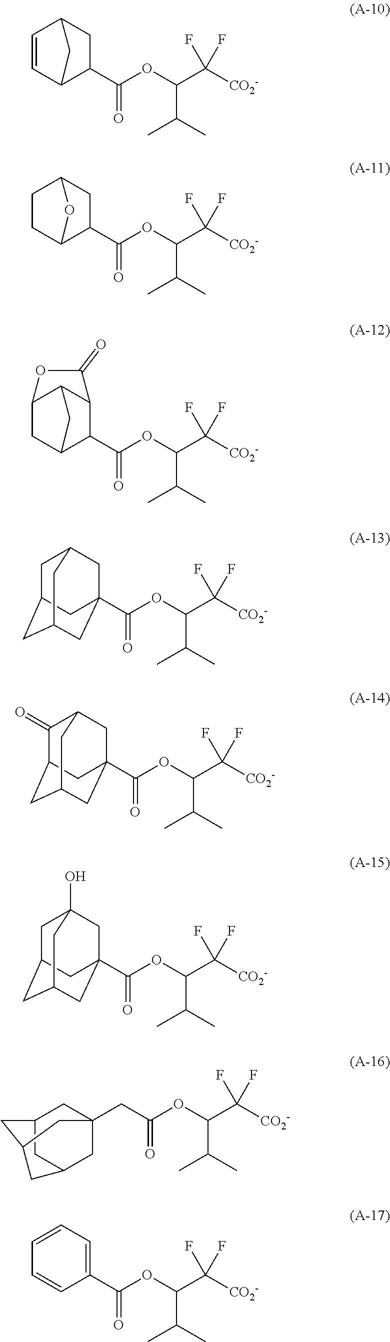

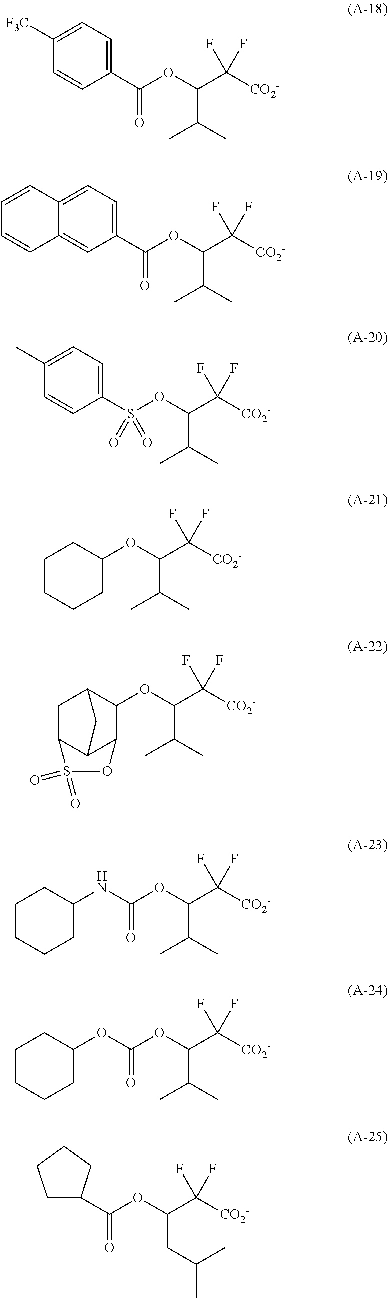

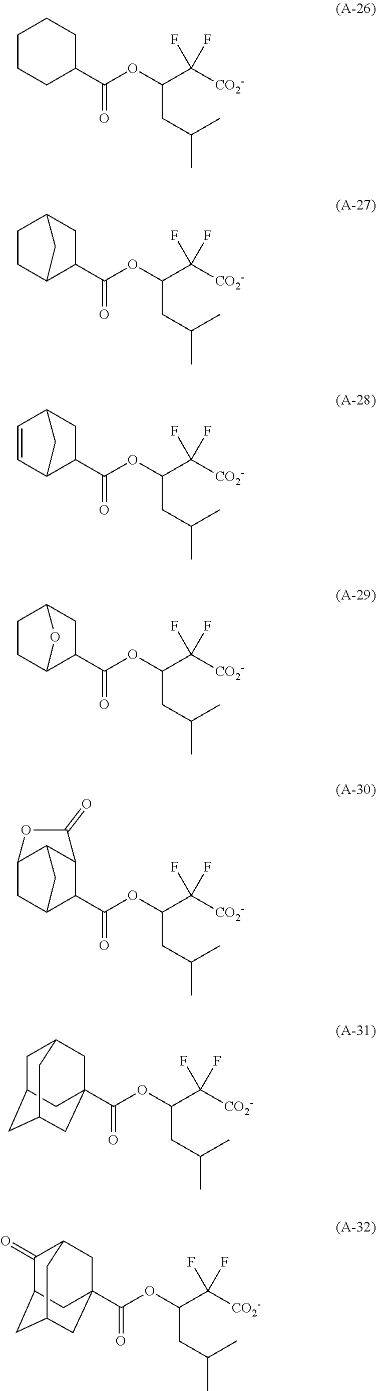

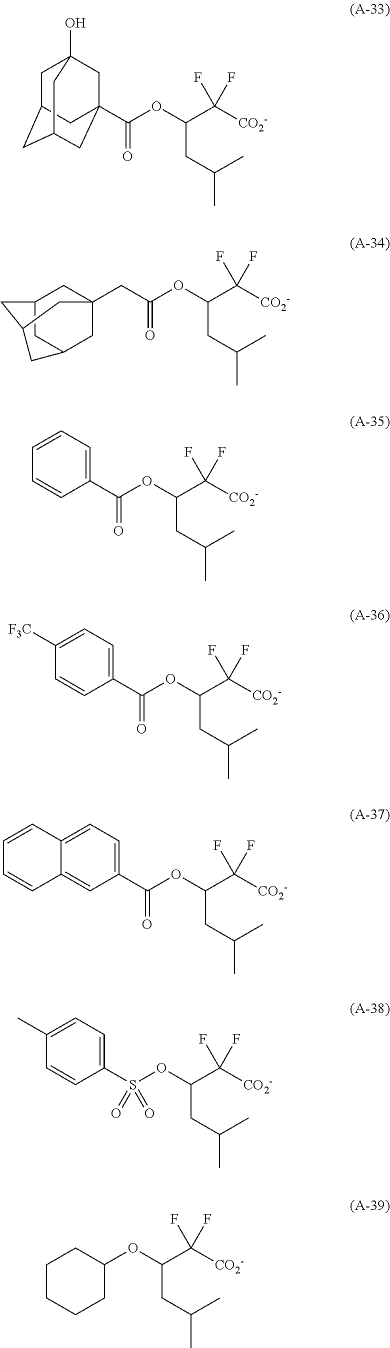

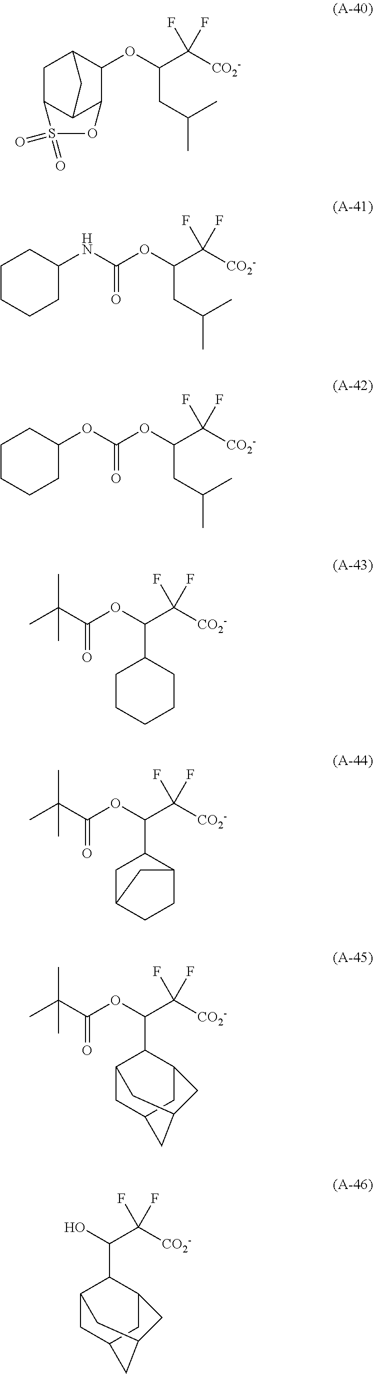

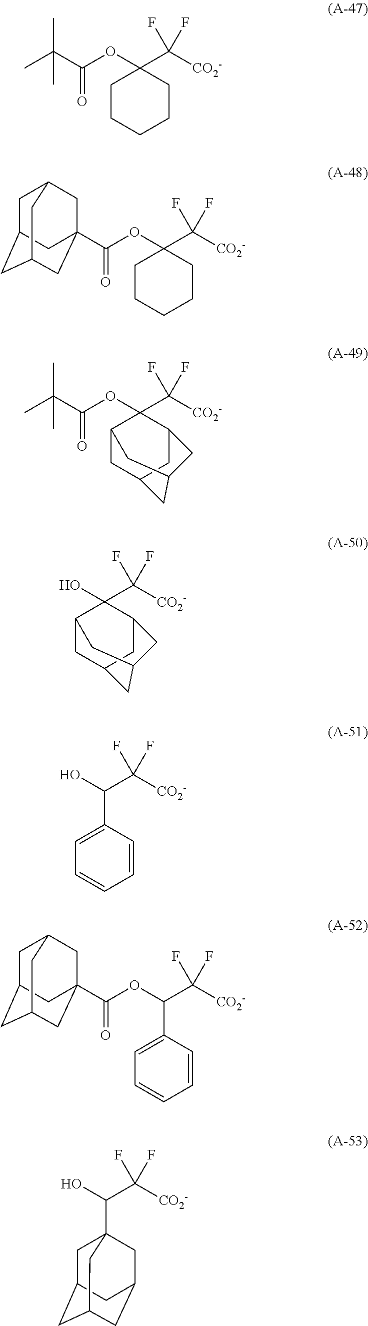

The lower limit of the content of the acid generating agent (B2) with respect to an entirety of the acid generating component (B) is preferably 20% by mass, more preferably 30% by mass, and still more preferably 40% by mass. The upper limit of the content of the acid generating agent (B2) is preferably 90% by mass, more preferably 80% by mass, and still more preferably 70% by mass. When the content of the acid generating agent (B2) falls within the above range, the radiation-sensitive resin composition enables the LWR performance, etc. to be more improved. One, or two or more types of the acid generating agent (B2) may be used.

Other Acid Generating Agent

Other acid generating agent is exemplified by an onium salt compound, an N-sulfonylimidoxy compound, a sulfonimide compound, a halogen-containing compound, a diazoketone compound and the like, other than the acid generating agent (B1) and the acid generating agent (B2). Specific examples of the other acid generating agent include compounds disclosed in paragraphs [0080] to [0113] of Japanese Unexamined Patent Application, Publication No. 2009-134088, and the like. One, or two or more types of the other acid generating agent may be used.

The lower limit of the total content of the acid generating agent (B1) and the acid generating agent (B2) with respect to an entirety of the acid generating component (B) is preferably 70% by mass, more preferably 80% by mass, and still more preferably 90% by mass. The upper limit of the total content of the acid generating agent (B1) and the acid generating agent (B2) is, for example, 100% by mass. When the total content of the acid generating agent (B1) and the acid generating agent (B2) falls within the above range, the radiation-sensitive resin composition enables the LWR performance, etc. to be more improved.

The lower limit of the content of the acid generating component (B) with respect to 100 parts by mass of the polymer component (A) is preferably 1 part by mass, more preferably 5 parts by mass, still more preferably 10 parts by mass, and particularly preferably 15 parts by mass. The upper limit of the content of the acid generating component (B) is preferably 50 parts by mass, more preferably 40 parts by mass, still more preferably 30 parts by mass, and particularly preferably 25 parts by mass. When the content of the acid generating component (B) falls within the above range, the radiation-sensitive resin composition enables the LWR performance, etc. to be more improved.

### (C) Acid Diffusion Control Agent

The radiation-sensitive resin composition may contain, as needed, the acid diffusion control agent (C) (wherein, any agent corresponding to the acid generating component (B) is excluded). The acid diffusion control agent (C) is exemplified by a nitrogen-containing compound, as well as a photodegradable base that generates a weak acid through photosensitization upon an exposure, and the like. The acid diffusion control agent (C) controls in the resist film, a diffusion phenomenon of the acid generated from the acid generating component (B) upon the exposure, thereby achieving an effect of inhibiting an undesired chemical reaction in light-unexposed regions. In addition, the radiation-sensitive resin composition may have improved storage stability, and the resolution as a resist can be more improved. Furthermore, alteration of the resist pattern line width resulting from varying post exposure time delay, from the exposure until the development treatment, can be inhibited, thereby enabling the radiation-sensitive resin composition that is superior in process stability to be obtained.

The nitrogen-containing compound is exemplified by a compound represented by the following formula (6) (hereinafter, may be also referred to as “nitrogen-containing compound (I)”), a compound having two nitrogen atoms (hereinafter, may be also referred to as “nitrogen-containing compound (II)”), a compound having three nitrogen atoms (hereinafter, may be also referred to as “nitrogen-containing compound (III)”), an amide group-containing compound, an urea compound, a nitrogen-containing heterocyclic compound, and the like.

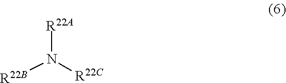

In the above formula (6), R^{22A}, R^{22B} and R^{22C} each independently represent a hydrogen atom, a linear, branched or cyclic alkyl group, an aryl group or an aralkyl group which may be each substituted.

Examples of the nitrogen-containing compound (I) include: monoalkylamines such as n-hexylamine; dialkylamines such as di-n-butylamine; trialkylamines such as triethylamine and tri-n-pentylamine; aromatic amines such as aniline and 2,6-di-i-propylaniline; and the like.

Examples of the nitrogen-containing compound (II) include ethylene diamine, N,N,N′,N′-tetramethylethylenediamine and the like.

Examples of the nitrogen-containing compound (III) include: polyamine compounds such as polyethyleneimine and polyallylamine; polymers of dimethylaminoethylacrylamide, etc.; and the like.

Examples of the amide group-containing compound include formamide, N-methylformamide, N,N-dimethylformamide, acetamide, N-methylacetamide, N,N-dimethylacetamide, propionamide, benzamide, pyrrolidone, N-methylpyrrolidone, and the like.

Examples of the urea compound include urea, methylurea, 1,1-dimethylurea, 1,3-dimethylurea, 1,1,3,3-tetramethylurea, 1,3-diphenylurea, tributylthiourea, and the like.

Examples of the nitrogen-containing heterocyclic compound include: pyridines such as pyridine and 2-methylpyridine; morpholines such as N-propylmorpholine and N-(undecan-1-ylcarbonyloxyethyl)morpholine; pyrazines; pyrazoles; and the like.

As the nitrogen-containing compound, a nitrogen-containing compound having an acid-labile group may be also used. Examples of the nitrogen-containing compound having an acid-labile group include N-t-butoxycarbonylpiperidine, N-t-butoxycarbonylimidazole, N-t-butoxycarbonylbenzimidazole, N-t-butoxycarbonyl-2-phenylbenzimidazole, N-(t-butoxycarbonyl)di-n-octylamine, N-(t-butoxycarbonyl)diethanolamine, N-(t-butoxycarbonyl)dicyclohexylamine, N-(t-butoxycarbonyl)diphenylamine, N-t-butoxycarbonyl-4-hydroxypiperidine, N-t-amyloxycarbonyl-4-hydroxypiperidine, and the like.

As the nitrogen-containing compound, the nitrogen-containing compound (I) and the nitrogen-containing heterocyclic compound are preferred, the trialkylamines, the aromatic amines and the morpholines are more preferred, and tri-n-pentylamine, 2,6-di-i-propylaniline and N-(undecan-1-ylcarbonyloxyethyl)morpholine are still more preferred.

Examples of the photodegradable base include onium salt compounds, e.g., a sulfonium salt compound represented by the following formula (7-1), an iodonium salt compound represented by the following formula (7-2), and the like.

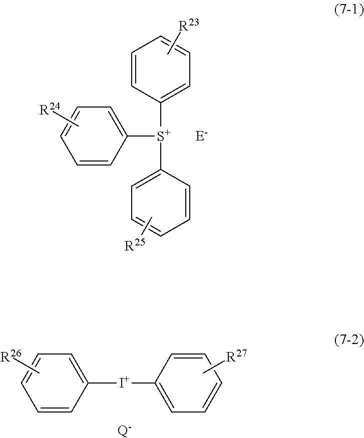

In the above formulae (7-1) and (7-2), R²³ to R²⁷ each independently represent a hydrogen atom, an alkyl group, an alkoxy group, a hydroxy group or a halogen atom; and E⁻ and Q⁻ each independently represent OH⁻, R^{α}—COO⁻, R^{α}—N⁻—SO₂—R^{β} or an anion represented by the following formula (7-3), wherein R^{α}s each independently represent an alkyl group, a monovalent alicyclic saturated hydrocarbon group, an aryl group or an aralkyl group, and R^{β} represents a fluorinated alkyl group.

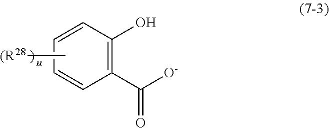

In the above formula (7-3), R²⁸ represents an alkyl group having 1 to 12 carbon atoms, a fluorinated alkyl group having 1 to 12 carbon atoms or an alkoxy group having 1 to 12 carbon atoms; and u is an integer of 0 to 2, wherein in a case in which u is 2, two R²⁸s may be identical or different.

Examples of the photodegradable base include compounds represented by the following formulae, and the like.

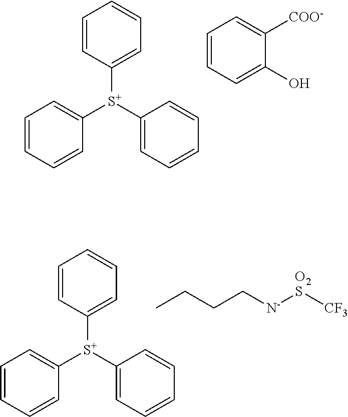

Of these, as the photodegradable base, a sulfonium salt is preferred, a triarylsulfonium salt is more preferred, and triphenylsulfonium salicylate is still more preferred.

In the case in which the radiation-sensitive resin composition contains the acid diffusion control agent (C), the lower limit of the content of the acid diffusion control agent (C) with respect to 100 parts by mass of the polymer component (A) is preferably 0.1 parts by mass, more preferably 0.5 parts by mass, still more preferably 1 part by mass, and particularly preferably 3 parts by mass. The upper limit of the content of the acid diffusion control agent (C) is preferably 20 parts by mass, more preferably 15 parts by mass, still more preferably 10 parts by mass, and particularly preferably 8 parts by mass. The radiation-sensitive resin composition may contain one, or two or more types of the acid diffusion control agent (C).

### (D) Solvent

The solvent (D) is not particularly limited as long as solvent (D) is capable of dissolving or dispersing at least the polymer component (A) and the acid generating component (B), as well as the acid diffusion control agent (C) and the like which may be contained as desired.

The solvent (D) is exemplified by an alcohol solvent, an ether solvent, a ketone solvent, an amide solvent, an ester solvent, a hydrocarbon solvent, and the like.

Examples of the alcohol solvent include:

aliphatic monohydric alcohol solvents having 1 to 18 carbon atoms such as 4-methyl-2-pentanol and n-hexanol;

alicyclic monohydric alcohol solvents having 3 to 18 carbon atoms such as cyclohexanol;

polyhydric alcohol solvents having 2 to 18 carbon atoms such as 1,2-propylene glycol;

polyhydric alcohol partial ether solvents having 3 to 19 carbon atoms such as propylene glycol monomethyl ether; and the like.

Examples of the ether solvent include:

dialkyl ether solvents such as diethyl ether, dipropyl ether, dibutyl ether, dipentyl ether, diisoamyl ether, dihexyl ether and diheptyl ether;

cyclic ether solvents such as tetrahydrofuran and tetrahydropyran;

aromatic ring-containing ether solvents such as diphenyl ether and anisole; and the like.

Examples of the ketone solvent include:

chain ketone solvents such as acetone, methyl ethyl ketone, methyl n-propyl ketone, methyl n-butyl ketone, diethyl ketone, methyl iso-butyl ketone, 2-heptanone, ethyl n-butyl ketone, methyl n-hexyl ketone, di-iso-butyl ketone and trimethylnonanone;

cyclic ketone solvents such as cyclopentanone, cyclohexanone, cycloheptanone, cyclooctanone and methylcyclohexanone;

2,4-pentanedione, acetonylacetone and acetophenone; and the like.

Examples of the amide solvent include:

cyclic amide solvents such as N,N′-dimethylimidazolidinone and N-methypyrrolidone;

chain amide solvents such as N-methylformamide, N,N-dimethylformamide, N,N-diethylformamide, acetamide, N-methylacetamide, N,N-dimethylacetamide and N-methylpropionamide; and the like.

Examples of the ester solvent include:

monocarboxylic acid ester solvents such as n-butyl acetate and ethyl lactate;

polyhydric alcohol carboxylate solvents such as propylene glycol acetate;

polyhydric alcohol partial ether carboxylate solvents such as propylene glycol monomethyl ether acetate;

polyhydric carboxylic acid diester solvents such as diethyl oxalate;

carbonate solvents such as dimethyl carbonate and diethyl carbonate; and the like.

Examples of the hydrocarbon solvent include:

aliphatic hydrocarbon solvents having 5 to 12 carbon atoms such as n-pentane and n-hexane;

aromatic hydrocarbon solvents having 6 to 16 carbon atoms such as toluene and xylene; and the like.

Of these, the ester solvent and the ketone solvent are preferred, the polyhydric alcohol partial ether carboxylate solvent and the cyclic ketone solvent are more preferred, and propylene glycol monomethyl ether acetate and cyclohexanone are still more preferred. One, or two or more types of the solvent (D) may be contained.

### (E) Polymer

The polymer (E) has a greater percentage content by mass of fluorine atoms than that of the polymer component (A). The radiation-sensitive resin composition may contain the polymer (E) as, for example, a water repellent additive.

The lower limit of the percentage content of fluorine atoms in the polymer (E) is preferably 1% by mass, more preferably 2% by mass, still more preferably 4% by mass, and particularly preferably 7% by mass. The upper limit of the percentage content of fluorine atoms in the polymer (E) is preferably 60% by mass, more preferably 40% by mass, and still more preferably 30% by mass. The percentage content of fluorine atoms in a polymer (% by mass) may be determined by ¹³C-NMR spectrumspectroscopy or the like to analyze a structure of the polymer, and a calculation based on the structure.

The structural unit included in the polymer (E) is exemplified by the following structural unit (Ea), the following structural unit (Eb) and the like. The polymer (E) may have one, or two or more types of the structural unit (Ea) and the structural unit (Eb), respectively.

Structural Unit (Ea) p The structural unit (Ea) is represented by the following formula (8a). Due to having the structural unit (Ea), the polymer (E) enables the percentage content of fluorine atoms to be adjusted.

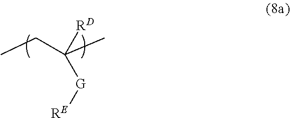

In the above formula (8a), R^{D} represents a hydrogen atom, a fluorine atom, a methyl group or a trifluoromethyl group; G represents a single bond, an oxygen atom, a sulfur atom, —CO—O—, —SO₂—O—NH—, —CO—NH— or —O—CO—NH—; and R^{E} represents a monovalent fluorinated chain hydrocarbon group having 1 to 6 carbon atoms or a monovalent fluorinated alicyclic hydrocarbon group having 4 to 20 carbon atoms.

Examples of the monovalent fluorinated chain hydrocarbon group having 1 to 6 carbon atoms which may be represented by R^{E} include a trifluoromethyl group, a 2,2,2-trifluoroethyl group, a perfluoroethyl group, a 2,2,3,3,3-pentafluoropropyl group, a 1,1,1,3,3,3-hexafluoropropyl group, a perfluoro-n-propyl group, a perfluoro-i-propyl group, a perfluoro-n-butyl group, a perfluoro-i-butyl group, a perfluoro-t-butyl group, a 2,2,3,3,4,4,5,5-octafluoropentyl group, a perfluorohexyl group and the like.

Examples of the monovalent fluorinated alicyclic hydrocarbon group having 4 to 20 carbon atoms which may be represented by R^{E} include a monofluorocyclopentyl group, a difluorocyclopentyl group, a perfluorocyclopentyl group, a monofluorocyclohexyl group, a difluorocyclohexyl group, a perfluorocyclohexylmethyl group, a fluoronorbornyl group, a fluoroadamantyl group, a fluorobornyl group, a fluoroisobornyl group, a fluorotricyclodecyl group, a fluorotetracyclodecyl group and the like.

Examples of a monomer that gives the structural unit (Ea) include:

(meth)acrylic acid esters each having a fluorinated chain hydrocarbon group, e.g.,

linear partially fluorinated alkyl (meth)acrylic acid esters such as a 2,2,2-trifluoroethyl (meth)acrylic acid ester,

branched partially fluorinated alkyl (meth)acrylic acid esters such as a 1,1,1,3,3,3-hexafluoro-i-propyl (meth)acrylic acid ester,

linear perfluoroalkyl (meth)acrylic acid esters such as a perfluoroethyl (meth)acrylic acid ester, and branched perfluoroalkyl (meth)acrylic acid esters such as a perfluoro-i-propyl (meth)acrylic acid ester;

(meth)acrylic acid esters each having a fluorinated alicyclic hydrocarbon group, e.g.,

(meth)acrylic acid esters each having a monocyclic fluorinated alicyclic saturated hydrocarbon group, such as a perfluorocyclohexylmethyl (meth)acrylic acid ester, a monofluorocyclopentyl (meth)acrylic acid ester and a perfluorocyclopentyl (meth)acrylic acid ester; and

(meth)acrylic acid esters each having a polycyclic fluorinated alicyclic saturated hydrocarbon group, such as a fluoronorbornyl (meth)acrylic acid ester; and the like. Of these, the (meth)acrylic acid esters each having a fluorinated chain hydrocarbon group are preferred, the linear partially fluorinated alkyl (meth)acrylic acid esters are more preferred, and a 2,2,2-trifluoroethyl (meth)acrylic acid ester is still more preferred.

In the case in which the polymer (E) has the structural unit (Ea), the lower limit of the proportion of the structural unit (Ea) contained with respect to the total structural units constituting the polymer (E) is preferably 5 mol %, more preferably 10 mol %, and still more preferably 20 mol %. The upper limit of the proportion of the structural unit (Ea) contained is preferably 95 mol %, more preferably 75 mol %, and still more preferably 50 mol %. When the proportion of the structural unit (Ea) contained falls within such a range, exhibiting a greater dynamic contact angle of a surface of a resist film in liquid immersion lithography is enabled.

### Structural Unit (Eb)

The structural unit (Eb) is represented by the following formula (8b). Since the polymer (E) has increased hydrophobicity due to having the structural unit (Eb), providing a more increased dynamic contact angle of a surface of a resist film formed from the radiation-sensitive resin composition is enabled.

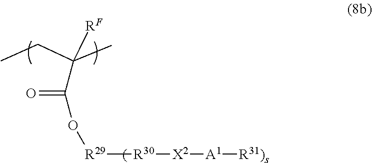

In the above formula (8b), R^{F} represents a hydrogen atom, a fluorine atom, a methyl group or a trifluoromethyl group; R²⁹ represents a hydrocarbon group having 1 to 20 carbon atoms and having a valency of (s+1), wherein R²⁹ may include an oxygen atom, a sulfur atom, —NR′—, a carbonyl group, —CO—O— or —CO—NH— bonded to an end on the side of R³⁰; R′ represents a hydrogen atom or a monovalent organic group; R³⁰ represents a single bond, a divalent chain hydrocarbon group having 1 to 10 carbon atoms or a divalent alicyclic hydrocarbon group having 4 to 20 carbon atoms; X² represents a divalent fluorinated chain hydrocarbon group having 1 to 20 carbon atoms; A¹ represents an oxygen atom, —NR″—, —CO—O—* or —SO₂—O—*; R″ represents a hydrogen atom or a monovalent organic group, wherein * denotes a bonding site to R³¹, wherein R³¹ represents a hydrogen atom or a monovalent organic group; and s is an integer of 1 to 3, wherein in a case in which s is 2 or 3, a plurality of R³⁰s, a plurality of X²s, a plurality of A¹s and a plurality of R³¹s are each identical to or different from each other.

R³¹ preferably represents a hydrogen atom in light of enabling solubility of the polymer (E) in an alkaline developer solution to be improved.

The monovalent organic group which may be represented by R³¹ is exemplified by an acid-labile group, an alkali-labile group, or a hydrocarbon group having 1 to 30 carbon atoms that may have a substituent, and the like.

### Structural Unit (Ec)

The polymer (E) may also have a structural unit that includes an acid-labile group (hereinafter, may be also referred to as “structural unit (Ec)”, wherein those corresponding to the structural units (Ea) and (Eb) are excluded) in addition to the structural units (Ea) and (Eb). Due to the polymer (E) having the structural unit (Ec), the resist pattern obtained can have more favorable shape. The structural unit (Ec) is exemplified by the structural unit (III) in the polymer component (A), and the like.

In a case in which the polymer (E) has the structural unit (Ec), the lower limit of the proportion of the structural unit (Ec) contained with respect to the total structural units constituting the structural unit (Ec) is preferably 5 mol %, more preferably 25 mol %, and still more preferably 50 mol %. The upper limit of the proportion of the structural unit (Ec) contained is preferably 90 mol %, more preferably 80 mol %, and still more preferably 70 mol %.

The lower limit of the content of the polymer (E) with respect to 100 parts by mass of the polymer component (A) is preferably 0.1 parts by mass, more preferably 1 part by mass, and still more preferably 2 parts by mass. The upper limit of the content of the polymer (E) is preferably 20 parts by mass, more preferably 10 parts by mass, and still more preferably 7 parts by mass. The radiation-sensitive resin composition may contain one, or two or more types of the polymer (E).

### Other Optional Components

The radiation-sensitive resin composition may contain other optional component(s) in addition to the components (A) to (E). The other optional component is exemplified by a localization accelerator, a surfactant, an alicyclic skeleton-containing compound, a sensitizing agent and the like. One, or two or more types of these other optional components may be used in combination.

Localization Accelerator

The localization accelerator achieves the effect that for example, in the case of the radiation-sensitive resin composition of the embodiment of the present invention containing the polymer (E), the polymer (E) is more efficiently segregated in the surface region of the resist film. When the radiation-sensitive resin composition contains the localization accelerator, the amount of the polymer (E) added can be decreased than ever before. Therefore, elution of the component(s) from the resist film into a liquid immersion liquid is further inhibited, and/or quicker liquid immersion lithography by high speed scanning is enabled, without impairing the LWR performance, etc. As a result, an improvement of hydrophobicity of the surface of the resist film is enabled which can inhibit defects caused by the liquid immersion such as watermark defects. The localization accelerator which may be used is exemplified by a low molecular weight compound having a relative permittivity of no less than 30 and no greater than 200, and having a boiling point at 1 atmospheric pressure of no less than 100° C. Specific examples of such a compound include a lactone compound, a carbonate compound, a nitrile compound, a polyhydric alcohol, and the like.

Examples of the lactone compound include γ-butyrolactone, valerolactone, mevalonic lactone, norbornanelactone and the like. Examples of the carbonate compound include propylene carbonate, ethylene carbonate, butylene carbonate, vinylene carbonate and the like. Examples of the nitrile compound include succinonitrile and the like. Examples of the polyhydric alcohol include glycerin and the like.

In the case in which the radiation-sensitive resin composition contains the localization accelerator, the lower limit of the content of the localization accelerator with respect to 100 parts by mass of the polymer component (A) is preferably 10 parts by mass, more preferably 15 parts by mass, still more preferably 20 parts by mass, and particularly preferably 25 parts by mass. The upper limit of the content of the localization accelerator is preferably 500 parts by mass, more preferably 300 parts by mass, still more preferably 200 parts by mass, and particularly preferably 100 parts by mass.

Surfactant

The surfactant exerts the effect of improving the coating property, striation, developability, and the like. Examples of the surfactant include: nonionic surfactants such as polyoxyethylene lauryl ether, polyoxyethylene stearyl ether, polyoxyethylene oleyl ether, polyoxyethylene n-octylphenyl ether, polyoxyethylene n-nonylphenyl ether, polyethylene glycol dilaurate and polyethylene glycol distearate; and the like. Examples of the commercially available product of the surfactant include KP341 (Shin-Etsu Chemical Co., Ltd.), Polyflow No. 75 and Polyflow No. 95 (all available from Kyoeisha Chemical Co., Ltd.), EFTOP EF301, EFTOP EF303 and EFTOP EF352 (all available from Tochem Products Co. Ltd.), Megaface F171 and Megaface F173 (all available from DIC, Corporation), Fluorad FC430 and Fluorad FC431 (all available from Sumitomo 3M Limited), ASAHI GUARD AG710, Surflon S-382, Surflon SC-101, Surflon SC-102, Surflon SC-103,

Surflon SC-104, Surflon SC-105 and Surflon SC-106 (all available from Asahi Glass Co., Ltd.), and the like. In the case in which the radiation-sensitive resin composition contains the surfactant, the upper limit of the content of the surfactant with respect to 100 parts by mass of the polymer component (A) is preferably 0.1 parts by mass, and more preferably 0.3 parts by mass. The upper limit of the content is preferably 2 parts by mass.

Alicyclic Skeleton-Containing Compound

The alicyclic skeleton-containing compound achieves the effect of improving dry etching resistance, a pattern configuration, adhesiveness to a substrate, and the like.

Examples of the alicyclic skeleton-containing compound include:

adamantane derivatives such as 1-adamantanecarboxylic acid, 2-adamantanone and t-butyl 1-adamantanecarboxylate;

deoxycholic acid esters such as t-butyl deoxycholate, t-butoxycarbonylmethyl deoxycholate and 2-ethoxyethyl deoxycholate;

lithocholic acid esters such as t-butyl lithocholate, t-butoxycarbonylmcthyl lithocholate and 2-ethoxyethyl lithocholate;

3-[2-hydroxy-2,2-bis(trifluoromethyl)ethyl]tetracyclo[4.4.0.1^{2,5}.1^{7,10}]dodecane, 2-hydroxy-9-methoxycarbonyl-5-oxo-4-oxa-tricyclo[4.2.1.0^{3,7}]nonane; and the like. In the case in which the radiation-sensitive resin composition contains the alicyclic skeleton-containing compound, the upper limit of the content of the alicyclic skeleton-containing compound with respect to 100 parts by mass of the polymer component (A) is preferably 5 parts by mass.

Sensitizing Agent

The sensitizing agent exhibits the action of increasing the amount of the acid generated from the acid generating component (B) or the like, and achieves the effect of improving “apparent sensitivity” of the radiation-sensitive resin composition. Examples of the sensitizing agent include carbazoles, acetophenones, benzophenones, naphthalenes, phenols, biacetyl, eosin, rose bengal, pyrenes, anthracenes, phenothiazines, and the like. In the case in which the radiation-sensitive resin composition contains the sensitizing agent, the upper limit of the content of the sensitizing agent with respect to 100 parts by mass of the polymer component (A) is preferably 2 parts by mass.

### Preparation Procedure of Radiation-Sensitive Resin Composition

The radiation-sensitive resin composition may be prepared, for example, by mixing the polymer component (A) and the acid generating component (B), as well as the optional component which is added as needed such as the acid diffusion control agent (C) and the solvent (D) in a certain ratio, and preferably filtrating the mixture thus obtained through a filter having a pore size of about 0.2 μm, for example. The lower limit of the solid content concentration of the radiation-sensitive resin composition is preferably 0.1% by mass, more preferably 0.5% by mass, and still more preferably 1% by mass. The upper limit of the solid content concentration is preferably 50% by mass, more preferably 20% by mass, and still more preferably 5% by mass.

### Resist Pattern-Forming Method

The resist pattern-forming method according to another embodiment of the present invention includes: the step of applying directly or indirectly on one face of a substrate the radiation-sensitive resin composition of the embodiment of the invention (hereinafter, may be also referred to as “applying step”); the step of exposing the resist film obtained by the applying step (hereinafter, may be also referred to as “exposure step”); and the step of developing the resist film exposed (hereinafter, may be also referred to as “development step”).

Since the radiation-sensitive resin composition is used in the resist pattern-forming method, formation of a resist pattern being accompanied by less LWR, less CDU and high resolution and being superior in rectangular configuration of the cross-sectional shape is enabled, with a superior exposure latitude attained. Each step will be described below.

Applying Step

In this step, the radiation-sensitive resin composition is applied directly or indirectly on one face of the substrate. Thus, a resist film is formed. The substrate on which the resist film is formed is exemplified by a conventionally well-known substrate such as a silicon wafer, a wafer coated with silicon dioxide or aluminum, and the like. In addition, an organic or inorganic antireflective film disclosed in, for example, Japanese Examined Patent Application, Publication No. H6-12452, Japanese Unexamined Patent Application,

Publication No. S59-93448, or the like may be formed on the substrate. An application procedure is exemplified by spin-coating, cast coating, roll-coating, and the like. After the application, prebaking (PB) may be carried out as needed for evaporating the solvent remaining in the coating film. The lower limit of the temperature for PB is preferably 60° C., and more preferably 80° C. The upper limit of the temperature for PB is preferably 140° C., and more preferably 120° C. The lower limit of the time period for PB is preferably 5 sec, and more preferably 10 sec. The upper limit of the time period for PB is preferably 600 sec, and more preferably 300 sec. The lower limit of the average thickness of the resist film formed is preferably 10 nm, and more preferably 20 nm. The upper limit of the average thickness is preferably 1,000 nm, and more preferably 500 nm.

In the case of conducting the liquid immersion lithography, when the radiation-sensitive resin composition does not contain the polymer (E), for example, a protective film for liquid immersion which is insoluble in the liquid immersion medium may be provided on the formed resist film, for the purpose of preventing a direct contact of the resist film with the liquid immersion medium. As the protective film for liquid immersion, either a solvent-peelable protective film that is peeled by a solvent prior to the development step (see Japanese Unexamined Patent Application, Publication No. 2006-227632), or a developer solution-peelable protective film that is peeled concomitant with the development in the development step (see, PCT International Publication Nos. 2005/069076 and 2006/035790) may be used. However, in light of the throughput, a developer solution-peelable protective film for liquid immersion is preferably used.

Exposure Step

In this step, the resist film obtained by the applying step is exposed. This exposure is carried out by irradiation with an exposure light through a photomask (as the case may be, through a liquid immersion medium such as water). Examples of the exposure light include electromagnetic waves such as visible light rays, ultraviolet rays, far ultraviolet rays, extreme ultraviolet rays (EUV), X-rays and y-rays; charged particle rays such as electron beams and a-rays, and the like, which may be selected in accordance with a line width of the intended pattern. Of these, far ultraviolet rays, EUV and electron beams are preferred; an ArF excimer laser beam (wavelength: 193 nm), a KrF excimer laser beam (wavelength: 248 nm), EUV and an electron beam are more preferred; an ArF excimer laser beam, EUV and an electron beam are still more preferred; and EUV and an electron beam are particularly preferred.

In a case where the exposure is carried out by liquid immersion lithography, examples of the liquid immersion liquid for use in the exposure include water, fluorine-containing inert liquids, and the like. It is preferred that the liquid immersion liquid is transparent to an exposure wavelength, and has a temperature coefficient of the refractive index as small as possible so that distortion of an optical image projected onto the film is minimized. In particular, when an ArF excimer laser beam is used as an exposure light, it is preferred to use water in light of availability and ease of handling thereof in addition to the aforementioned considerations. When water is used, a slight amount of an additive which reduces the surface tension of water and imparts enhanced surfactant power may be added. It is preferred that the additive hardly dissolves a resist film on a wafer and has a negligible influence on an optical coating of an inferior face of a lens. The water for use is preferably distilled water.

It is preferred that post exposure baking (PEB) is carried out after the exposure to promote dissociation of the acid-labile group included in the polymer component (A), etc.

mediated by the acid generated from the acid generating component (B), etc., upon the exposure in exposed regions of the resist film. This PEB enables a difference in solubility of the resist film in a developer solution between the light-exposed regions and light-unexposed regions to be increased. The lower limit of the temperature for PEB is preferably 50° C., and more preferably 80° C. The upper limit of the temperature is preferably 180° C., and more preferably 130° C. The lower limit of the time period for PEB is preferably 5 sec, and more preferably 10 sec. The upper limit of the time period is preferably 600 sec, and more preferably 300 sec.

According to the resist pattern-forming method, since the radiation-sensitive resin composition of the embodiment of the present invention is used, inhibition of contraction of the resist film during PEB is enabled.

Development Step

In this step, the resist film exposed is developed. Accordingly, formation of a predetermined resist pattern is enabled. After the development, washing with a rinse agent such as water or an alcohol, followed by drying is typically carried out. The development procedure in the development step may be carried out by either development with an alkali, or development with an organic solvent.

In the case of the development with an alkali, the developer solution for use in the development is exemplified by alkaline aqueous solutions prepared by dissolving at least one alkaline compound such as sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethylamine, ethyldimethylamine, triethanolamine, tetramethylammonium hydroxide (TMAH), pyrrole, piperidine, choline, 1,8-diazabicyclo-[5.4.0]-7-undecene, 1,5-diazabicyclo-[4.3.0]-5-nonene, etc., and the like. Of these, an aqueous TMAH solution is preferred, and a 2.38% by mass aqueous TMAH solution is more preferred.

In the case of the development with an organic solvent, the developer solution is exemplified by: an organic solvent such as a hydrocarbon solvent, an ether solvent, an ester solvent, a ketone solvent and an alcohol solvent; a solvent containing the organic solvent; and the like. Exemplary organic solvent includes one, or two or more types of the solvents exemplified as the solvent (C) for the radiation-sensitive resin composition, and the like. Of these, the ester solvent and the ketone solvent are preferred. The ester solvent is preferably an acetic acid ester solvent, and more preferably n-butyl acetate. The ketone solvent is preferably a chain ketone, and more preferably 2-heptanone. The lower limit of the content of the organic solvent in the developer solution is preferably 80% by mass, more preferably 90% by mass, still more preferably 95% by mass, and particularly preferably 99% by mass. Components other than the organic solvent in the organic solvent developer solution are exemplified by water, silicone oil, and the like.

Examples of the development procedure include: a dipping procedure in which the substrate is immersed for a given time period in the developer solution charged in a container; a puddle procedure in which the developer solution is placed to form a dome-shaped bead by way of the surface tension on the surface of the substrate for a given time period to conduct a development; a spraying procedure in which the developer solution is sprayed onto the surface of the substrate; a dynamic dispensing procedure in which the developer solution is continuously applied onto the substrate that is rotated at a constant speed while scanning with a developer solution-application nozzle at a constant speed; and the like.

### EXAMPLES

Hereinafter, the present invention is explained in detail by way of Examples, but the present invention is not in any way limited to these Examples. Measuring methods for various types of physical properties are shown below.

Mw, Mn and Mw/Mn

The Mw and the Mn were determined by gel permeation chromatography (GPC) using GPC columns (“G2000HXL”×2, “G3000HXL”×1 and “G4000HXL”×1, Tosoh Corporation) under the analytical conditions involving a flow rate: 1.0 mL/min, an elution solvent: tetrahydrofuran, a sample concentration: 1.0% by mass, an amount of injected sample: 100 μL, a column temperature: 40° C., and a detector: differential refractometer, with mono-dispersed polystyrene as a standard. The dispersity index (Mw/Mn) was calculated from the results of the determination of the Mw and the Mn.

¹³C-NMR Analysis

An analysis of determining the proportion of each structural unit contained in each polymer (mol %) was performed by using a nuclear magnetic resonance apparatus (JEOL, Ltd., “JNM-ECX400”), with deuterodimethyl sulfoxide as a measurement solvent.

### Syntheses of Polymer Components (A)

Monomers used for syntheses of polymer components (A) are shown below.

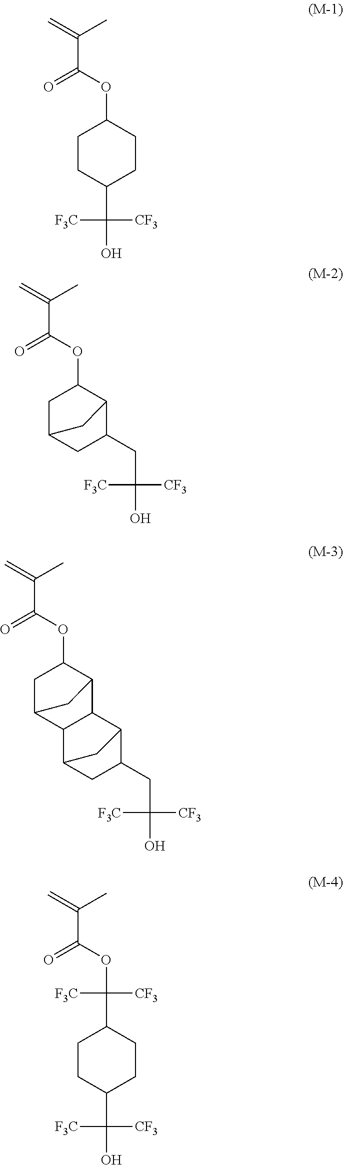

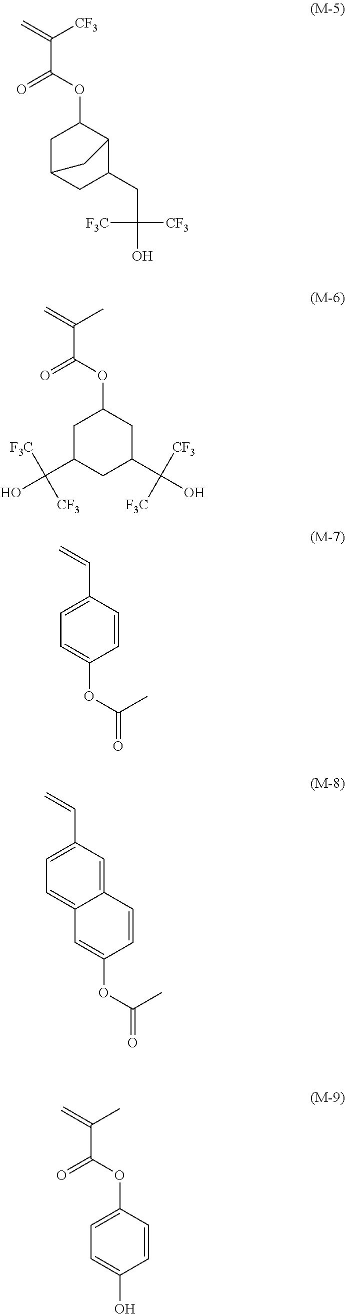

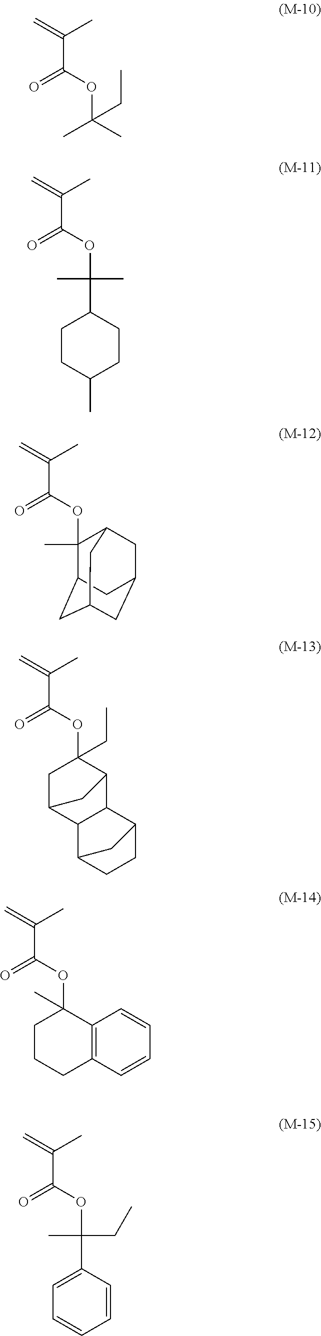

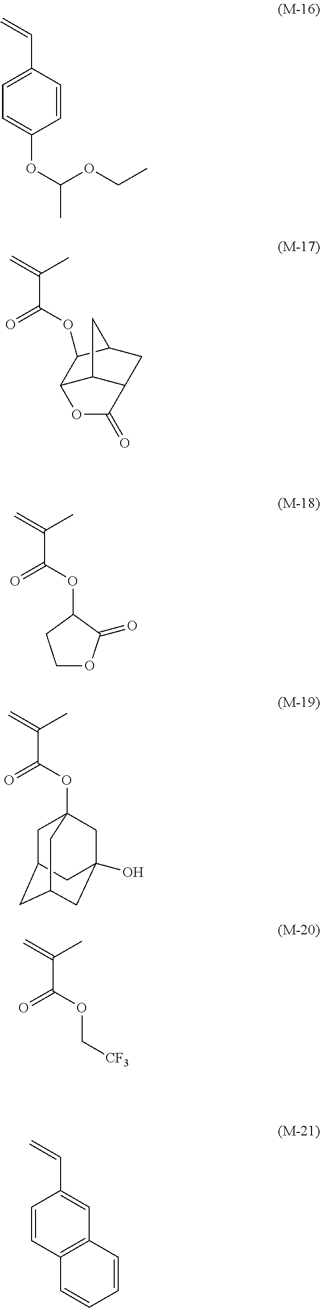

It is to be noted that the compounds (M-1) to (M-6) give the structural units (I), and the compounds (M-7) to (M-9) give the structural units (II), and the compounds (M-10) to (M-16) give the structural units (III), respectively. The compounds (M-17) to (M-21) give other structural units.

### Synthesis Example 1

### Synthesis of Polymer (A-1)

After 34.42 g (20 mol %) of the compound (M-1), 33.40 g (40 mol %) of the compound (M-7), 32.17 g (40 mol %) of the compound (M-10), 4.23 g of AIBN (5 mol % with respect to a total of the monomers) as a radical polymerization initiator, and 1.56 g of t-dodecyl mercaptan (1.5 mol % with respect to a total of the monomers) as a chain transfer agent were dissolved in 200 g of propylene glycol monomethyl ether, the mixture was subjected to polymerization for 9 hrs in a nitrogen atmosphere, while the reaction temperature was maintained at 70° C. After the completion of the polymerization reaction, the polymerization reaction mixture was added dropwise to 1,000 g of n-hexane to permit solidification purification of a polymer. Thereafter, to the polymer was added 150 g of propylene glycol monomethyl ether, and 150 g of methanol, 25 g of triethylamine and 5 g of water were further added. The mixture was subjected to a hydrolysis reaction for 8 hrs while refluxing at a boiling point was allowed. After the completion of the reaction, the solvent and triethylamine were distilled off in vacuo, the resulting polymer was dissolved in 150 g of acetone, which was then added dropwise to 2,000 g of water to permit solidification, and the produced white powder was collected by filtration and was dried at 50° C. for 17 hrs to give a polymer (A-1) as a white powder (amount: 68.3 g; yield: 68%). The polymer (A-1) had the Mw of 6,700, and the Mw/Mn of 1.54. In addition, the result of the ¹³C-NMR analysis indicated that the proportions of the structural units derived from (M-1), p-hydroxystyrene and (M-10) were 20.5 mol %, 40.0 mol % and 39.5 mol %, respectively.

### Synthesis Examples 2 to 4, 7, 9 to 11, 14 and 16

### Syntheses of Polymers (A-2) to (A-4), (A-7), (A-9) to (A-11), (A-14) and (A-16)

Polymers (A-2) to (A-4), (A-7), (A-9) to (A-11), (A-14) and (A-16) were synthesized by carrying out a similar operation to Synthesis Example 1 except that each monomer of the type and the using amount shown in the following Table 1 was used. The proportion (mol %), yield (%), the Mw and the Mw/Mn of each structural unit of the polymer thus obtained are shown together in Table 1.

### Synthesis Example 5

### Synthesis of Polymer (A-5)

A monomer solution was prepared by dissolving 33.09 g (20 mol %) of the compound (M-5), 14.23 g (20 mol %) of the compound (M-9), 47.95 g (55 mol %) of the compound (M-15), and 4.72 g (5 mol %) of the compound (M-19) in 200 g of 2-butanone, and then adding thereto 3.28 g of AIBN (5 mol % with respect to a total of the monomers) as a radical polymerization initiator. Next, after a 500 mL three-necked flask charged with 100 g of 2-butanone was purged with nitrogen for 30 min, the liquid was heated to 80° C. while stirring, and thereto was added dropwise the monomer solution prepared as described above using a dropping funnel over 3 hours. The time when dropwise addition was started was assumed to be a start time point of the polymerization reaction, and the polymerization reaction was carried out for 6 hours. After completion of the polymerization reaction, the polymerization reaction liquid was cooled with water to a temperature of no greater than 30° C. The cooled polymerization reaction liquid was charged into 2,000 g of methanol, and a white powder thus precipitated was collected by filtration. After the collected white powder was washed with 80 g of methanol twice, filtration and drying at 50° C. for 17 hours were carried out. Accordingly, a white powdery polymer (A-5) was obtained (amount: 72.8 g; yield: 73%). The polymer (A-5) had the Mw of 6,900, and the Mw/Mn of 1.55. n addition, as a result of the ¹³C-NMR analysis, the proportions of the structural units derived from (M-5), (M-9), (M-15) and (M-19) were 21.7 mol %, 20.5 mol %, 53.6 mol % and 4.2 mol %, respectively.

### Synthesis Examples 8, 12, 13 and 15

### Syntheses of Polymers (A-8), (A-12), (A-13) and (A-15)

Polymers (A-8), (A-12), (A-13) and (A-15) were synthesized by carrying out a similar operation to Synthesis Example 5 except that each monomer of the type and the using amount shown in the following Table 1 was used. The proportion (mol %), yield (%), the Mw and the Mw/Mn of each structural unit of the polymer thus obtained are shown together in Table 1.

### Synthesis Example 6

### Synthesis of Polymer (A-6)

Under a nitrogen stream, 100 g of propylene glycol monomethyl ether was heated to 80° C. A mixed solution of 39.34 g (25 mol %) of the compound (M-2), 23.35 g (30 mol %) of the compound (M-9), 33.59 g (40 mol %) of the compound (M-16), 3.72 g (5 mol %) of the compound (M-18), 200 g of propylene glycol monomethyl ether and 5.03 g (5 mol % with respect to a total of the monomers) of dimethyl 2,2′-azobisisobutyrate (Wako Pure Chemical Industries, Ltd., “V-601”) was added dropwise to the liquid over 2 hrs with stirring. After completion of the dropwise addition, the mixture was further stirred at 80° C. for 4 hrs. After the reaction liquid was allowed to cool, reprecipitation was permitted with a large amount of hexane/ethyl acetate, and the precipitate thus obtained was dried in vacuo to give a polymer (A-6) (amount: 68.5 g; yield: 69%). The polymer (A-6) had the Mw of 7,200, and the Mw/Mn of 1.52. In addition, the result of the ¹³C-NMR analysis indicated that the proportions of the structural units derived from (M-2), (M-9), (M-16) and (M-18) were 24.2 mol %, 30.4 mol %, 40.4 mol % and 5.0 mol %, respectively.

TABLE 1

| | | | | (B1) Acid generating | | (B2) Acid generating | | (C) Acid diffusion | | | |
|---|---|---|---|---|---|---|---|---|---|---|---|
| | Radiation- | (A) Polymer component | | agent | | agent | | control agent | | (D) Solvent | |
| | sensitive | | content | | content | | content | | content | | content |
| | resin | | (parts by | | (parts by | | (parts by | | (parts by | | (parts by |
| | composition | type | mass) | type | mass) | type | mass) | type | mass) | type | mass) |
| Example 19 | J-19 | A-4 | 100 | B-13 | 10 | B-4/B-8 | 5/5 | C-1 | 5 | D-1/D-2 | 4,510/1,930 |
| Example 20 | J-20 | A-5 | 100 | B-12 | 10 | B-3/B-7 | 4/4 | C-3 | 5 | D-1/D-2 | 4,510/1,930 |
| Example 21 | J-21 | A-1/A-3 | 50/50 | B-9 | 9 | B-7 | 8 | C-3 | 5 | D-1/D-2 | 4,510/1,930 |
| Example 22 | J-22 | A-2/A-4 | 50/50 | B-10 | 10 | B-2 | 7 | C-3 | 5 | D-1/D-2 | 4,510/1,930 |
| Example 23 | J-23 | A-6/A-8 | 50/50 | B-ll | 12 | B-3 | 8 | C-1 | 5 | D-1/D-2 | 4,510/1,930 |
| Example 24 | J-24 | A-11/A-12 | 50/50 | B-12 | 10 | B-4 | 10 | C-3 | 5 | D-1/D-2 | 4,510/1,930 |
| Example 25 | J-25 | A-11/A-12 | 60/40 | B-13 | 10 | B-5 | 10 | C-3 | 5 | D-1/D-2 | 4,510/1,930 |
| Example 26 | J-26 | A-2/A-15 | 90/10 | B-14 | 6 | B-6 | 10 | C-3 | 5 | D-1/D-2 | 4,510/1,930 |
| Example 27 | J-27 | A-4/A-15 | 90/10 | B-14 | 6 | B-8 | 12 | C-3 | 5 | D-1/D-2 | 4,510/1,930 |
| Example 28 | J-28 | A-2/A-16 | 80/20 | B-14 | 6 | B-1 | 7 | C-3 | 5 | D-1/D-2 | 4,510/1,930 |
| Example 29 | J-29 | A-13/A-14 | 40/60 | B-9 | 10 | B-3 | 8 | C-4 | 5 | D-1/D-2 | 4,510/1,930 |
| Comparative | CJ-1 | A-13 | 100 | B-9 | 10 | B-3 | 8 | C-4 | 5 | D-1/D-2 | 4,510/1,930 |
| Example 1 | | | | | | | | | | | |
| Comparative | CJ-2 | A-14 | 100 | B-9 | 10 | B-3 | 8 | C-4 | 5 | D-1/D-2 | 4,510/1,930 |
| Example 2 | | | | | | | | | | | |
| Comparative | CJ-3 | A-2 | 100 | B-9 | 10 | — | — | C-4 | 5 | D-1/D-2 | 4,510/1,930 |
| Example 3 | | | | | | | | | | | |
| Comparative | CJ-4 | A-2 | 100 | B-10/B-11 | 4/6 | — | — | C-4 | 5 | D-1/D-2 | 4,510/1,930 |
| Example 4 | | | | | | | | | | | |
| Comparative | CJ-5 | A-2 | 100 | — | — | B-2 | 16 | C-4 | 5 | D-1/D-2 | 4,510/1,930 |
| Example 5 | | | | | | | | | | | |
| Comparative | CJ-6 | A-2 | 100 | — | — | B-7 | 16 | C-4 | 5 | D-1/D-2 | 4,510/1,930 |
| Example 6 | | | | | | | | | | | |
| Comparative | CJ-7 | A-2 | 100 | — | — | B-2/B-7 | 8/8 | C-4 | 5 | D-1/D-2 | 4,510/1,930 |
| Example 7 | | | | | | | | | | | |

### Preparation of Radiation-Sensitive Resin Composition

Components other than the polymer components (A) used in preparation of the radiation-sensitive resin compositions are as shown below.

(B) Acid Generating Components

Each structural formula is shown below.

Acid generating agents (B2): compounds (B-1) to (B-⁻8)

Acid generating agents (B1): compounds (B-9) to (B-14)

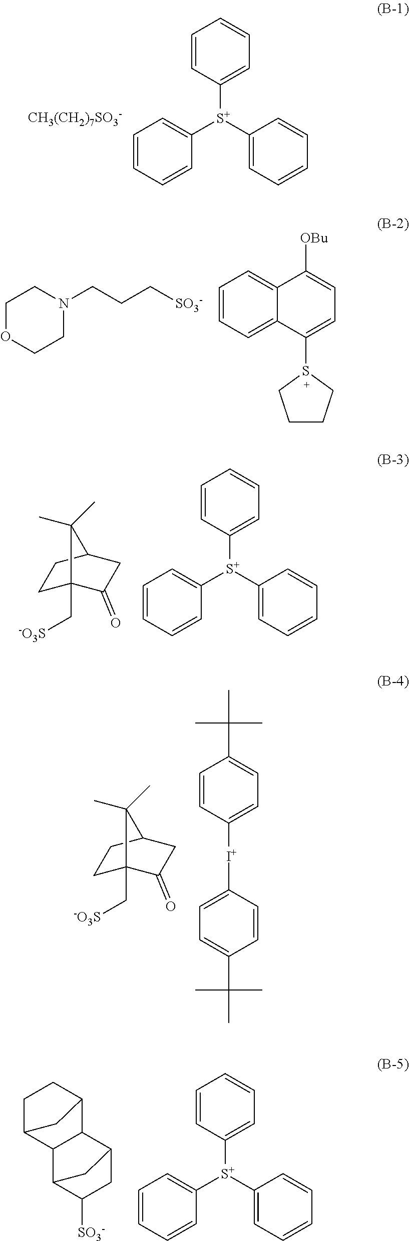

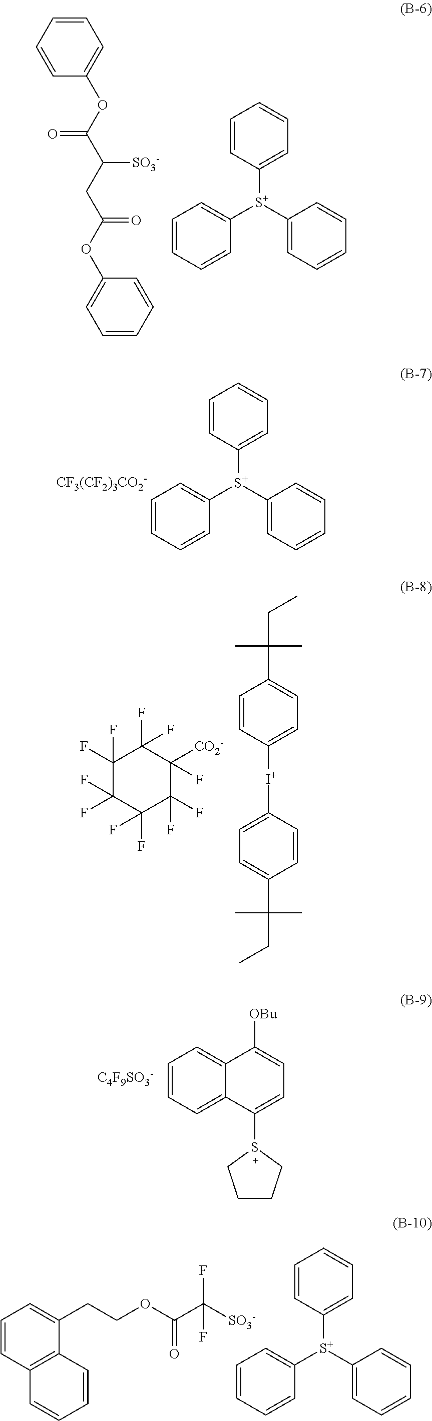

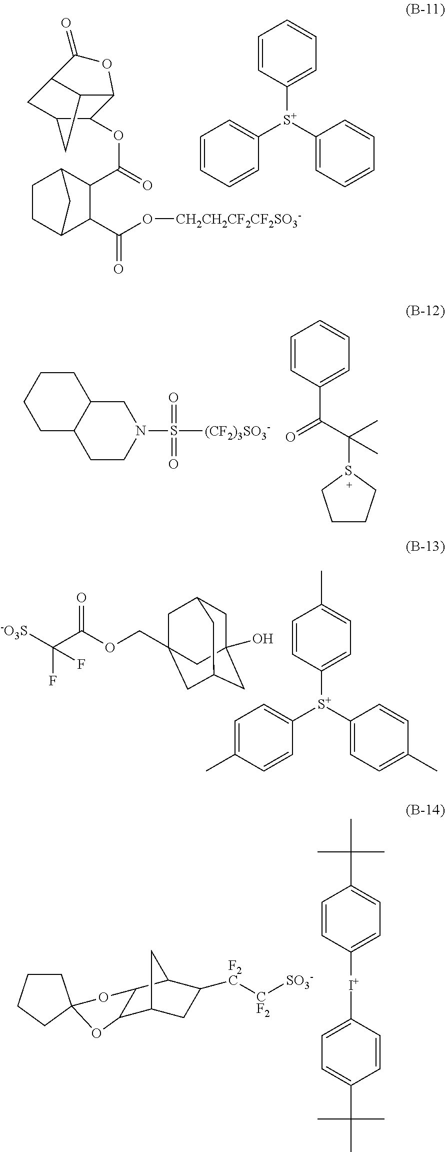

(C) Acid Diffusion Control Agent

Each structural formula is shown below.

C-1: triphenylsulfonium salicylate

C-2: N-(undecan-1-ylcarbonyloxyethyl)morpholine

C-3: 2,6-dii-propylaniline

C-4: tri-n-pentylamine

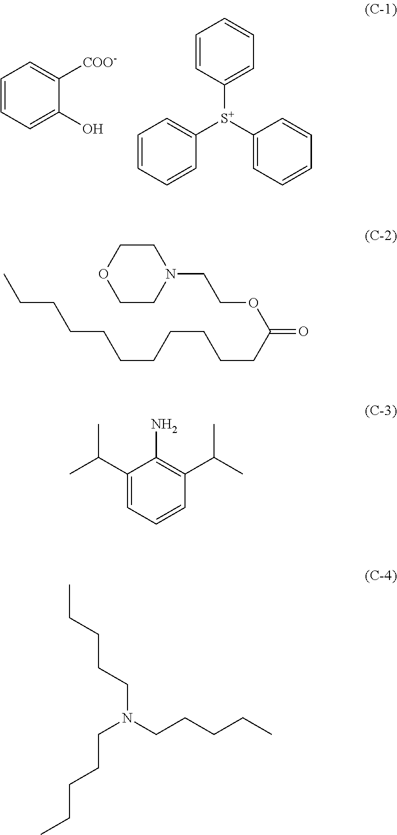

(D) Solvent

D-1: propylene glycol monomethyl ether acetate

D-2: cyclohexanone

### Example 1

### Preparation of Radiation-Sensitive Resin Composition (J-1)

A radiation-sensitive resin composition (J-1) was prepared by blending 100 parts by mass of (A-1) as the polymer component (A), 10 parts by mass of (B-9) as the acid generating agent (B1), 7 parts by mass of (B-1) as the acid generating agent (B2), 5 parts by mass of (C-1) as the acid diffusion control agent (C), and 4,510 parts by mass of (D-1) and 1,930 parts by mass of (D-2) as the solvent (D), and then filtering the resultant mixture through a membrane filter of 20 nm.

### Examples 2 to 29 and Comparative Examples 1 to 7

### Preparation of Radiation-Sensitive Resin Compositions (J-2) to (J-29) and (CJ-1) to (CJ-7)

Radiation-sensitive resin compositions (J-2) to (J-29) and (CJ-1) to (CJ-7) were prepared by a similar operation to that of Example 1 except that the type and the content of each component used were as shown in Tables 2 and 3 below. In Tables 2 and 3, “-” indicates that the corresponding component was not used.

TABLE 2

| | | | | (B1) Acid generating | | (B2) Acid generating | | (C) Acid diffusion | | | |
|---|---|---|---|---|---|---|---|---|---|---|---|
| | Radiation- | (A) Polymer component | | agent | | agent | | control agent | | (D) Solvent | |
| | sensitive | | content | | content | | content | | content | | content |
| | resin | | (parts by | | (parts by | | (parts by | | (parts by | | (parts by |
| | composition | type | mass) | type | mass) | type | mass) | type | mass) | type | mass) |
| Example 1 | J-1 | A-1 | 100 | B-9 | 10 | B-1 | 7 | C-1 | 5 | D-1/D-2 | 4,510/1,930 |
| Example 2 | J-2 | A-2 | 100 | B-9 | 10 | B-3 | 8 | C-2 | 5 | D-1/D-2 | 4,510/1,930 |
| Example 3 | J-3 | A-3 | 100 | B-10 | 10 | B-2 | 8 | C-3 | 5 | D-1/D-2 | 4,510/1,930 |
| Example 4 | J-4 | A-4 | 100 | B-1 | 12 | B-3 | 8 | C-4 | 5 | D-1/D-2 | 4,510/1,930 |
| Example 5 | J-5 | A-5 | 100 | B-12 | 10 | B-4 | 10 | C-2 | 5 | D-1/D-2 | 4,510/1,930 |
| Example 6 | J-6 | A-6 | 100 | B-13 | 10 | B-5 | 8 | C-2 | 5 | D-1/D-2 | 4,510/1,930 |
| Example 7 | J-7 | A-7 | 100 | B-14 | 5 | B-6 | 10 | C-1 | 5 | D-1/D-2 | 4,510/1,930 |
| Example 8 | J-8 | A-8 | 100 | B-14 | 5 | B-8 | 15 | C-4 | 5 | D-1/D-2 | 4,510/1,930 |
| Example 9 | J-9 | A-9 | 100 | B-14 | 5 | B-1 | 5 | C-4 | 5 | D-1/D-2 | 4,510/1,930 |
| Example 10 | J-10 | A-10 | 100 | B-14 | 5 | B-2 | 10 | C-4 | 5 | D-1/D-2 | 4,510/1,930 |
| Example 11 | J-11 | A-2 | 100 | B-14 | 5 | B-4 | 10 | C-1 | 5 | D-1/D-2 | 4,510/1,930 |
| Example 12 | J-12 | A-6 | 100 | B-9 | 10 | B-6 | 10 | C-3 | 5 | D-1/D-2 | 4,510/1,930 |
| Example 13 | J-13 | A-7 | 100 | B-12 | 10 | B-6 | 10 | C-3 | 5 | D-1/D-2 | 4,510/1,930 |
| Example 14 | J-14 | A-8 | 100 | B-13 | 5 | B-6 | 10 | C-4 | 5 | D-1/D-2 | 4,510/1,930 |
| Example 15 | J-15 | A-9 | 100 | B-9 | 9 | B-7/B-8 | 4/4 | C-4 | 5 | D-1/D-2 | 4,510/1,930 |
| Example 16 | J-16 | A-10 | 100 | B-10 | 4 | B-2/B-3 | 5/5 | C-4 | 5 | D-1/D-2 | 4,510/1,930 |
| Example 17 | J-17 | A-16 | 100 | B-11/B-12 | 6/5 | B-7 | 8 | C-4 | 5 | D-1/D-2 | 4,510/1,930 |
| Example 18 | J-18 | A-3 | 100 | B-13/B-14 | 5/5 | B-4 | 9 | C-3 | 5 | D-1/D-2 | 4,510/1,930 |

TABLE 3

| | | | | (B1) Acid generating | | (B2) Acid generating | | (C) Acid diffusion | | | |
|---|---|---|---|---|---|---|---|---|---|---|---|
| | Radiation- | (A) Polymer component | | agent | | agent | | control agent | | (D) Solvent | |
| | sensitive | | content | | content | | content | | content | | content |
| | resin | | (parts by | | (parts by | | (parts by | | (parts by | | (parts by |
| | composition | type | mass) | type | mass) | type | mass) | type | mass) | type | mass) |
| Example 19 | J-19 | A-4 | 100 | B-13 | 10 | B-4/B-8 | 5/5 | C-1 | 5 | D-1/D-2 | 4,510/1,930 |
| Example 20 | J-20 | A-5 | 100 | B-12 | 10 | B-3/B-7 | 4/4 | C-3 | 5 | D-1/D-2 | 4,510/1,930 |
| Example 21 | J-21 | A-1/A-3 | 50/50 | B-9 | 9 | B-7 | 8 | C-3 | 5 | D-1/D-2 | 4,510/1,930 |
| Example 22 | J-22 | A-2/A-4 | 50/50 | B-10 | 10 | B-2 | 7 | C-3 | 5 | D-1/D-2 | 4,510/1,930 |
| Example 23 | J-23 | A-6/A-8 | 50/50 | B-11 | 12 | B-3 | 8 | C-1 | 5 | D-1/D-2 | 4,510/1,930 |
| Example 24 | J-24 | A-11/A-12 | 50/50 | B-12 | 10 | B-4 | 10 | C-3 | 5 | D-1/D-2 | 4,510/1,930 |
| Example 25 | J-25 | A-11/A-12 | 60/40 | B-13 | 10 | B-5 | 10 | C-3 | 5 | D-1/D-2 | 4,510/1,930 |
| Example 26 | J-26 | A-2/A-15 | 90/10 | B-14 | 6 | B-6 | 10 | C-3 | 5 | D-1/D-2 | 4,510/1,930 |
| Example 27 | J-27 | A-4/A-15 | 90/10 | B-14 | 6 | B-8 | 12 | C-3 | 5 | D-1/D-2 | 4,510/1,930 |
| Example 28 | J-28 | A-2/A-16 | 80/20 | B-14 | 6 | B-1 | 7 | C-3 | 5 | D-1/D-2 | 4,510/1,930 |
| Example 29 | J-29 | A-13/A-14 | 40/60 | B-9 | 10 | B-3 | 8 | C-4 | 5 | D-1/D-2 | 4,510/1,930 |
| Comparative | CJ-1 | A-13 | 100 | B-9 | 10 | B-3 | 8 | C-4 | 5 | D-1/D-2 | 4,510/1,930 |
| Example 1 | | | | | | | | | | | |
| Comparative | CJ-2 | A-14 | 100 | B-9 | 10 | B-3 | 8 | C-4 | 5 | D-1/D-2 | 4,510/1,930 |
| Example 2 | | | | | | | | | | | |
| Comparative | CJ-3 | A-2 | 100 | B-9 | 10 | — | — | C-4 | 5 | D-1/D-2 | 4,510/1,930 |
| Example 3 | | | | | | | | | | | |
| Comparative | CJ-4 | A-2 | 100 | B-10/B-11 | 4/6 | — | — | C-4 | 5 | D-1/D-2 | 4,510/1,930 |
| Example 4 | | | | | | | | | | | |
| Comparative | CJ-5 | A-2 | 100 | — | — | B-2 | 16 | C-4 | 5 | D-1/D-2 | 4,510/1,930 |
| Example 5 | | | | | | | | | | | |
| Comparative | CJ-6 | A-2 | 100 | — | — | B-7 | 16 | C-4 | 5 | D-1/D-2 | 4,510/1,930 |
| Example 6 | | | | | | | | | | | |
| Comparative | CJ-7 | A-2 | 100 | — | — | B-2/B-7 | 8/8 | C-4 | 5 | D-1/D-2 | 4,510/1,930 |
| Example 7 | | | | | | | | | | | |

Formation of Resist Pattern: Development with Alkali

The radiation-sensitive resin composition prepared as described above was applied on the surface of an 8-inch silicon wafer by using a spin coater (Tokyo Electron Limited, “CLEAN TRACK ACTS”), and subjected to PB at 110 ° C. for 60 sec. Cooling at 23° C. for 30 sec gave a resist film having an average film thickness of 50 nm. Next, this resist film was irradiated with an electron beam using a simplified electron beam writer (Hitachi, Ltd., “HL800D”; power: 50 KeV, electric current density: 5.0 A/cm²). After the irradiation, PEB was carried out at 110° C. for 60 sec. Thereafter, a development was carried out using a 2.38% by mass aqueous TMAH solution as an alkaline developer solution at 23° C. for 60 sec, followed by washing with water and drying to form a positive-tone resist pattern.

### Evaluations

The radiation-sensitive resin compositions were evaluated on the LWR performance, the CDU performance, the resolution, the rectangular configuration of the cross-sectional shape and the exposure latitude according to the following determinations, with respect to the resist patterns formed as described above. The results of the evaluations are shown in Table 4. A scanning electron microscope (Hitachi High-Technologies Corporation, “S-9380”) was used for the line-width measurement of the resist pattern. It is to be noted that an exposure dose at which a line width of 100 nm (L/S=1/1) was provided in forming the resist pattern was defined as an optimum exposure dose.

LWR Performance

The resist pattern formed as described above having a line width of 100 nm (L/S=1/1) was observed from above by using the scanning electron microscope. The line width was measured at arbitrary points of 50 in total, then a 3 Sigma value was determined from the distribution of the measurements, and the value was defined as “LWR performance (nm)”. The smaller value reveals less variance of the line width, indicating a better LWR performance. The LWR performance was evaluated to be: “favorable” in a case where the value of the LWR performance was no greater than 20 nm; and “unfavorable” in a case where the value of the LWR performance was greater than 20 nm.

CDU Performance

A resist pattern having a hole diameter of 100 nm (II=1/1) was observed from above the pattern using the scanning electron microscope. The hole diameter was measured at 25 points within the range of 1,000 nm×1,000 nm, and an averaged value of the hole diameters was determined. The averaged value was determined at arbitrary points of 50 in total, and a 3 Sigma value was determined from the distribution of the averaged values. The 3 Sigma value was defined as “CDU performance” (nm). The smaller value is more favorable since a better CDU performance is indicated, revealing less variance of the hole diameters in greater ranges. The CDU performance was evaluated to be: “favorable” in a case where the value of the CDU performance was no greater than 10 nm; and “unfavorable” in a case where the value of the CDU performance was greater than 10 nm.

Resolution

A dimension of the minimum resist pattern was measured which was resolved at the optimum exposure dose, and the measurement value was defined as “resolution (nm)”. The smaller value reveals successful formation of a finer pattern, indicating a better resolution.

The resolution was evaluated to be: “favorable” in a case where the formed line width was no greater than 50 nm; and “unfavorable” in a case where the formed line width was greater than 50 nm.

Rectangular Configuration of Cross-Sectional Shape

A cross-sectional shape of the resist pattern which was resolved at the optimum exposure dose described above was observed to measure a hole diameter Lb at the middle along an altitude direction of the resist pattern, and a hole diameter La at the top of the resist pattern. Then, La/Lb value was calculated, and the calculated value was employed as a marker for the rectangular configuration of the cross-sectional shape. The rectangularity of the cross-sectional shape was evaluated to be: “favorable” in a case where 0.9≤(La/Lb)≤1.1; and to be “unfavorable” in a case where (La/Lb)≤0.9, or 1.1≤(La/Lb).

Exposure Latitude

An exposure dose was varied in step of 1 μC/cm² within an exposure dose range including the optimum exposure dose, and a resist pattern was formed at each exposure dose. The line width of each resist pattern was measured using the scanning electron microscope. The exposure dose E (110) at which the line width of 110 nm was attained and the exposure dose E (90) at which the line width of 90 nm was attained were determined from the relationship between the line width obtained and the exposure dose, and the exposure latitude (%) was calculated using the following equation: exposure latitude=[E(110)−E(90)]×100/(optimum exposure dose). The greater “exposure latitude” value indicates a less variation of the dimension of the formed pattern with a variation of the exposure dose, leading to a higher process yield in the production of devices. The exposure latitude was evaluated to be: “favorable” in the case of the exposure latitude being no less than 20%; and to be “unfavorable” in the case of the exposure latitude being less than 20%.

TABLE 4

| | | LWR | CDU | | Rectangularity | Exposure |
|---|---|---|---|---|---|---|
| | Radiation-sensitive | performance | performance | Resolution | of cross- | latitude |
| | resin composition | (nm) | (nm) | (nm) | sectional shape | (%) |
| Example 1 | J-1 | 18 | 9 | 45 | 0.95 | 22.2 |
| Example 2 | J-2 | 17 | 8 | 47 | 0.94 | 21.4 |
| Example 3 | J-3 | 18 | 7 | 48 | 0.93 | 21.2 |
| Example 4 | J-4 | 16 | 6 | 45 | 0.95 | 23.0 |
| Example 5 | J-5 | 19 | 9 | 44 | 0.96 | 23.2 |
| Example 6 | J-6 | 17 | 8 | 45 | 0.96 | 22.9 |
| Example 7 | J-7 | 19 | 8 | 47 | 1.05 | 21.5 |
| Example 8 | J-8 | 18 | 9 | 47 | 0.93 | 23.5 |
| Example 9 | J-9 | 16 | 7 | 45 | 0.95 | 23.0 |
| Example 10 | J-10 | 17 | 7 | 48 | 1.05 | 21.5 |
| Example 11 | J-11 | 19 | 9 | 47 | 0.94 | 22.9 |
| Example 12 | J-12 | 17 | 9 | 48 | 0.95 | 21.2 |
| Example 13 | J-13 | 19 | 8 | 47 | 0.93 | 21.5 |
| Example 14 | J-14 | 18 | 8 | 47 | 0.95 | 23.2 |
| Example 15 | J-15 | 19 | 9 | 48 | 0.95 | 23.5 |
| Example 16 | J-16 | 16 | 9 | 45 | 1.05 | 23.5 |
| Example 17 | J-17 | 18 | 8 | 48 | 0.93 | 22.9 |
| Example 18 | J-18 | 18 | 8 | 48 | 1.05 | 24.8 |
| Example 19 | J-19 | 18 | 8 | 48 | 0.93 | 23.0 |
| Example 20 | J-20 | 19 | 6 | 45 | 1.05 | 24.8 |
| Example 21 | J-21 | 16 | 7 | 47 | 0.95 | 23.2 |
| Example 22 | J-22 | 19 | 7 | 45 | 0.95 | 24.8 |
| Example 23 | J-23 | 19 | 8 | 47 | 1.05 | 23.0 |
| Example 24 | J-24 | 18 | 9 | 47 | 0.93 | 23.2 |
| Example 25 | J-25 | 16 | 9 | 47 | 1.05 | 21.2 |
| Example 26 | J-26 | 18 | 8 | 45 | 0.95 | 23.5 |
| Example 27 | J-27 | 18 | 9 | 47 | 0.93 | 23.0 |
| Example 28 | J-28 | 19 | 9 | 45 | 1.05 | 21.5 |
| Example 29 | J-29 | 19 | 10 | 49 | 1.10 | 20.1 |
| Comparative | CJ-1 | 22 | 11 | 51 | 0.87 | 16.3 |
| Example 1 | | | | | | |
| Comparative | CJ-2 | 21 | 12 | 54 | 0.85 | 14.5 |
| Example 2 | | | | | | |
| Comparative | CJ-3 | 24 | 14 | 51 | 1.22 | 18.8 |
| Example 3 | | | | | | |
| Comparative | CJ-4 | 22 | 12 | 53 | 0.87 | 17.5 |
| Example 4 | | | | | | |
| Comparative | CJ-5 | 24 | 12 | 54 | 0.85 | 14.5 |
| Example 5 | | | | | | |
| Comparative | CJ-6 | 22 | 13 | 51 | 1.24 | 16.7 |
| Example 6 | | | | | | |
| Comparative | CJ-7 | 21 | 13 | 54 | 0.85 | 17.3 |
| Example 7 | | | | | | |

From the results shown in Table 4, the radiation-sensitive resin compositions of Examples were revealed to be superior in the LWR performance, the CDU performance, the resolution, the rectangular configuration of the cross-sectional shape and the exposure latitude. Meanwhile, it was also proven that the radiation-sensitive resin compositions of Comparative Examples were all inferior to those of Examples in terms of the performances described above. In general, an electron beam exposure is known to exhibit a similar tendency to the case of an EUV exposure, and therefore, the radiation-sensitive compositions of Examples are expected to be superior in the LWR performance, etc., also in the case of the EUV exposure.

The radiation-sensitive resin composition and the resist pattern-forming method according to the embodiments of the present invention enable a resist pattern to be formed, which is accompanied by less LWR, less CDU and high resolution and is superior in rectangular configuration of the cross-sectional shape while attaining superior exposure latitude. Therefore, these can be suitably used in manufacture of semiconductor devices in which further progress of miniaturization is expected in the future.

Obviously, numerous modifications and variations of the present invention are possible in light of the above teachings. It is therefore to be understood that within the scope of the appended claims, the invention may be practiced otherwise than as specifically described herein.

What is claimed is:

1. A radiation-sensitive resin composition comprising:
a polymer component comprising in a single polymer or different polymers, a first structural unit, a second structural unit and a third structural unit; and
a radiation-sensitive acid generating component comprising a first radiation-sensitive acid generating agent and a second radiation-sensitive acid generating agent:
wherein,
the first structural unit comprises a group represented by formula (1),
the second structural unit comprises a hydroxyl group bonded to an aromatic ring, and
the third structural unit comprises an acid-labile group,
and wherein,
an acid to be generated from the first radiation-sensitive acid generating agent is a first sulfonic acid, and an acid to be generated from the second radiation-sensitive acid generating agent is a second sulfonic acid or a carboxylic acid, wherein
the first sulfonic acid comprises: a first carbon atom that is adjacent to a first sulfo group; and a fluorine atom bonded to the first carbon atom, or a monovalent fluorinated hydrocarbon group bonded to the first carbon atom,
the second sulfonic acid comprises: a second carbon atom that is adjacent to a second sulfo group; and a third carbon atom that is adjacent to the second carbon atom, wherein neither a fluorine atom nor a monovalent fluorinated hydrocarbon group is bonded to the second carbon atom or the third carbon atom, and
the carboxylic acid comprises: a fourth carbon atom that is adjacent to a carboxy group; and a fluorine atom bonded to the fourth carbon atom, or a monovalent fluorinated hydrocarbon group bonded to the fourth carbon atom, 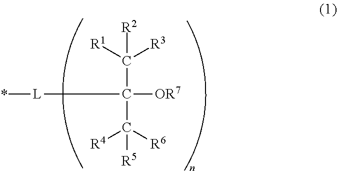
wherein, in the formula (1),
L represents an organic group having a valency of (n+1) and having 3 to 20 carbon atoms comprising an alicyclic structure having 3 to 20 ring atoms;
R¹ to R⁶ each independently represent a hydrogen atom, a halogen atom or a monovalent organic group having 1 to 20 carbon atoms, wherein at least one of R¹ to R⁶ represents a fluorine atom or an organic group comprising at least one fluorine atom;
R⁷ represents a hydrogen atom or a monovalent organic group having 1 to 20 carbon atoms;
n is an integer of 1 to 3, wherein in a case where n is no less than 2, a plurality of R¹s are identical or different, a plurality of R²s are identical or different, a plurality of R³s are identical or different, a plurality of R⁴s are identical or different, a plurality of R⁵s are identical or different, a plurality of R⁶s are identical or different, and a plurality of R⁷s are identical or different; and
* denotes a bonding site to a moiety other than the group represented by the formula (1) in the first structural unit.

2. The radiation-sensitive resin composition according to claim 1, wherein the second sulfonic acid to be generated from the second radiation-sensitive acid generating agent is represented by formula (2): 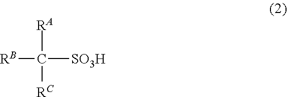
wherein, in the formula (2),
R^{A}, R^{B} and R^{C} each independently represent a hydrogen atom or a monovalent organic group having 1 to 20 carbon atoms, and optionally at least two of R^{A}, R^{B} and R^{C} taken together represent an alicyclic structure having 3 to 20 ring atoms together with the carbon atom to which the at least two of R^{A}, R^{B} and R^{C} bond, wherein a carbon atom serves as a bonding site to the carbon atom that is adjacent to the sulfo group in the organic group, and neither a fluorine atom nor a fluorinated hydrocarbon group is bonded to the carbon atom, and at least one of R^{A}, R^{B} and R^{C} represents the organic group.

3. The radiation-sensitive resin composition according to claim 1, wherein the first sulfonic acid to be generated from the first radiation-sensitive acid generating agent is represented by formula (3): 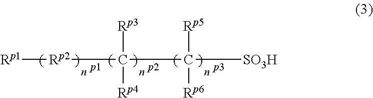
wherein, in the formula (3),
R^{p1} represents a monovalent group comprising a ring structure having no less than 6 ring atoms;
R^{p2} represents a divalent linking group;
R^{p3} and R^{p4} each independently represent a hydrogen atom, a fluorine atom, a monovalent hydrocarbon group having 1 to 20 carbon atoms or a monovalent fluorinated hydrocarbon group having 1 to 20 carbon atoms;
R^{p5} and R^{p6} each independently represent a fluorine atom or a monovalent fluorinated hydrocarbon group having 1 to 20 carbon atoms;
n^{p1} is an integer of 0 to 10;
n^{p2} is an integer of 0 to 10; and
n^{p3} is an integer of 1 to 10,
wherein
n^{p1}+n^{p2}+n^{p3} is no greater than 30, and
in a case in which n^{p1} is no less than 2, a plurality of R^{p2}s are identical or different,
in a case in which n^{p2} is no less than 2, a plurality of R^{p3}s are identical or different,
and a plurality of R^{p4}s are identical or different, and
in a case in which n^{p3} is no less than 2, a plurality of R^{p5}s are identical or different,
and a plurality of R^{p6}s are identical or different.

4. The radiation-sensitive resin composition according to claim 1, further comprising an acid diffusion control agent.

5. The radiation-sensitive resin composition according to claim 1, further comprising a polymer, wherein a percentage content by mass of fluorine atoms in the polymer is greater than a percentage content by mass of fluorine atoms in the polymer component.

6. The radiation-sensitive resin composition according to claim 1, wherein a content of the polymer component in terms of solid content equivalent in the radiation-sensitive resin composition is no less than 50% by mass.

7. The radiation-sensitive resin composition according to claim 1, wherein a proportion of the second structural unit contained with respect to total structural units constituting the polymer component is no less than 20 mol % and no greater than 70 mol %.

8. The radiation-sensitive resin composition according to claim 1, wherein a proportion of the first structural unit contained with respect to total structural units constituting the polymer component is no less than 5 mol % and no greater than 50 mol %.

9. The radiation-sensitive resin composition according to claim 1, wherein a total content of the first radiation-sensitive acid generating agent and the second radiation-sensitive acid generating agent with respect to an entirety of the radiation-sensitive acid generating component is no less than 70% by mass.

10. The radiation-sensitive resin composition according to claim 1, wherein a content of the first radiation-sensitive acid generating agent with respect to an entirety of the radiation-sensitive acid generating component is no less than 10% by mass.

11. A resist pattern-forming method comprising:
applying the radiation-sensitive resin composition according to claim 1 directly or indirectly on one face of a substrate to obtain a resist film;
exposing the resist film; and
developing the resist film exposed.

12. The resist pattern-forming method according to claim 11, wherein a radioactive ray to be used in the exposing is an extreme ultraviolet ray or an electron beam.
